(19) United States
(12) Patent Application Publication
(10) Pub. No.: US 2026/0338872 A1
(43) Pub. Date: Oct. 29, 2026

(54) SYSTEMS AND METHODS FOR IN-SITU DETERMINATION OF A THERMODYNAMIC STATE OF DEGRADATION OF AN ELECTROCHEMICAL CELL ASSEMBLY

(71) Applicant: Element Energy, Inc., Menlo Park, CA (US)

(72) Inventors: Maxwell Lee Wood, Los Angeles, CA (US); Georgy Zerkalov, Santa Clara, CA (US); Rainer Johannes Fasching, Mill Valley, CA (US)

(21) Appl. No.: 19/193,840

(22) Filed: Apr. 29, 2025

(51) Int. Cl. G01R 31/392; G01R 31/367; G01R 31/3835

(52) U.S. Cl. CPC G01R 31/392; G01R 31/367; G01R 31/3835

(57) ABSTRACT

A method for in-situ determination of a thermodynamic state of degradation of an electrochemical cell assembly includes (i) sensing voltage of the electrochemical cell assembly in-situ over one or more operating intervals of the electrochemical cell assembly, (ii) determining charge flowing between the electrochemical cell assembly and external circuitry over the one or more operating intervals of the electrochemical cell assembly, (iii) constructing a raw voltage profile representing voltage of the electrochemical cell assembly as a function of capacity of the electrochemical cell assembly, (iv) extracting a subset of the raw voltage profile to obtain an extracted voltage profile, (v) varying parameters of a model of the electrochemical cell assembly until one or more cost functions meet respective predetermined conditions, and (vi) determining the thermodynamic state of degradation of the electrochemical cell assembly at least partially based on the parameters of the model of the electrochemical cell assembly.

### BACKGROUND

A battery is a device including one or more electrochemical cells. While many types of electrochemical cells can be discharged and recharged multiple times, electrochemical cells tend to degrade with use as well as with time. Accordingly, an electrochemical cell that has been in service for an extended period may have a greater state of degradation (SOD), or a smaller state of health (SOH), than a new electrochemical cell of like type.

One popular electrochemical cell is the Lithium-ion (Li-ion) electrochemical cell. Examples of Li-ion electrochemical cells include Lithium Cobalt Oxide (LCO) electrochemical cells, Lithium Manganese Oxide (LMO) electrochemical cells, Lithium Nickel Manganese Cobalt Oxide (NMC) electrochemical cells, Lithium Iron Phosphate (LFP) electrochemical cells, Lithium Nickel Cobalt Aluminum Oxide (NCA) electrochemical cells, and Lithium Titanate (LTO) electrochemical cells. Li-ion electrochemical cells advantageously have a high energy density relative to most other rechargeable electrochemical cells. However, Li-ion electrochemical cells can easily be damaged by operation outside of their intended operating range, such as by overcharging the cell or by excessively discharging the cell. Additionally, the high energy density and use of flammable electrolyte of Li-ion electrochemical cells makes them susceptible to catching fire in case of electrochemical cell damage or electrochemical cell failure. Battery management systems, which control battery operation, such as battery charging and discharging, are therefore frequently used with batteries including Li-ion electrochemical cells (and other types of electrochemical cells) to help achieve long battery life and safe battery operation.

### SUMMARY

Disclosed herein are systems and methods for in-situ determination of a thermodynamic state of degradation (SOD) of an electrochemical cell assembly which significantly advance the state of the art of electrochemical cell monitoring. Particular embodiments are capable of determining SOD of an electrochemical cell assembly solely from data gathered during normal operation of the electrochemical cell assembly, such as data gathered during normal operation over an extended period. Consequently, these embodiments advantageously enable determination of thermodynamic SOD without disrupting operation of an electric vehicle, battery energy storage system, consumer electronic device, or other device where the electrochemical cell assembly is deployed. Additionally, certain embodiments supplement the data gathered during normal operation with data gathered during a slow charge or discharge of electrochemical cell assembly, to enhance accuracy of thermodynamic SOD determination. Furthermore, particular embodiments promote rapid and accurate SOD determination through advantageous use of cost functions to minimize a difference between a model of the electrochemical cell assembly and field data collected from the electrochemical cell assembly. Accordingly, the new systems and methods may enable determination of thermodynamic SOD in applications that would not be feasible using conventional techniques.

In an embodiment, a method for in-situ determination of a thermodynamic state of degradation of an electrochemical cell assembly includes (a) sensing voltage of the electrochemical cell assembly in-situ over one or more operating intervals of the electrochemical cell assembly to generate sensed voltage data, (b) determining charge flowing between the electrochemical cell assembly and external circuitry over the one or more operating intervals of the electrochemical cell assembly to generate sensed charge data, (c) constructing a raw voltage profile from each of (i) the sensed voltage data and (ii) the sensed charge data, the raw voltage profile representing voltage of the electrochemical cell assembly as a function of capacity of the electrochemical cell assembly, (d) extracting a subset of the raw voltage profile to obtain an extracted voltage profile, the extracted voltage profile including a plurality of open circuit voltage values of the electrochemical cell assembly, (e) varying parameters of a model of the electrochemical cell assembly until one or more cost functions meet respective predetermined conditions, each cost function representing error in the model of the electrochemical cell assembly with respect to data associated with the extracted voltage profile, and (f) after the one or more cost functions meet their respective predetermined conditions, determining the thermodynamic state of degradation of the electrochemical cell assembly at least partially based on the parameters of the model of the electrochemical cell assembly.

In an embodiment, a method for in-situ determination of a thermodynamic state of degradation of an electrochemical cell assembly includes (a) sensing voltage of the electrochemical cell assembly in-situ over one or more operating intervals of the electrochemical cell assembly, (b) determining charge flowing between the electrochemical cell assembly and external circuitry over the one or more operating intervals of the electrochemical cell assembly, (c) constructing a raw voltage profile from each of (i) the voltage of the electrochemical cell assembly sensed in-situ over the one or more operating intervals of the electrochemical cell assembly and (ii) the charge flowing between the electrochemical cell assembly and the external circuitry over the one or more operating intervals of the electrochemical cell assembly, the raw voltage profile representing voltage of the electrochemical cell assembly as a function of capacity of the electrochemical cell assembly, (d) extracting a subset of the raw voltage profile to obtain an extracted voltage profile, the extracted voltage profile including a plurality of open circuit voltage values of the electrochemical cell assembly, (e) generating one or more differential profiles of the electrochemical cell assembly, the one or more differential profiles including at least one of (i) a generated differential charge profile representing change in capacity of electrochemical cell assembly with respect to change in voltage of the electrochemical cell assembly, as a function of capacity of the electrochemical cell assembly, and (ii) a generated differential voltage profile representing change in voltage of the electrochemical cell assembly with respect to change in capacity of the electrochemical cell assembly, as a function of capacity of the electrochemical cell assembly, (f) varying parameters of a model of the electrochemical cell assembly until a plurality of cost functions meet respective predetermined conditions, each cost function representing error in the model of the electrochemical cell assembly with respect to one or more of (i) data associated with the extracted voltage profile and (ii) data associated with the one or more differential profiles, and (g) after the plurality of cost functions meet their respective predetermined conditions, determining the thermodynamic state of degradation of the electrochemical cell assembly at least partially based on the parameters of the model of the electrochemical cell assembly.

### BRIEF DESCRIPTION OF THE DRAWINGS

FIG. 1 is a schematic diagram of an electrical environment including a thermodynamic state of degradation determination system, according to an embodiment.

FIG. 2 is a schematic diagram of an example embodiment of an electrochemical cell assembly of the FIG. 1 electrical environment including a single electrochemical cell.

FIG. 3 is a schematic diagram of an example embodiment of an electrochemical cell assembly of the FIG. 1 electrical environment including a string of a plurality of electrochemical cells.

FIG. 4 is a schematic diagram of an example embodiment of an electrochemical cell assembly of the FIG. 1 electrical environment including two strings of a plurality of electrochemical cells.

FIG. 5 is a schematic diagram of an example embodiment of an electrochemical cell assembly of the FIG. 1 electrical environment including a plurality of electrochemical cells electrically coupled in parallel.

FIG. 6 is a block diagram of one embodiment of a controller of the FIG. 1 electrical environment.

FIG. 7 is a flow chart of a method for in-situ determination of a thermodynamic state of degradation of an electrochemical cell assembly, according to an embodiment.

FIG. 8 is a graph of capacity versus time illustrating one example of implementing rest states during a charging interval.

FIG. 9 is a graph of capacity versus time illustrating one example of implementing rest states during a discharging interval.

FIG. 10 is a table illustrating one example of sensed voltage data generated in the FIG. 7 method.

FIG. 11 is a table illustrating one example of sensed charge data generated in the FIG. 7 method.

FIG. 12 is a table illustrating one example of a raw voltage profile generated in the FIG. 7 method.

FIG. 13 is a table illustrating one example of an extracted voltage profile corresponding to charging of the FIG. 1 electrochemical cell assembly.

FIG. 14 is a table illustrating one example of an extracted voltage profile corresponding to discharging of the FIG. 1 electrochemical cell assembly.

FIG. 15 is a graph of voltage versus capacity illustrating examples of over-potential in one embodiment of the FIG. 1 electrochemical cell assembly including a single electrochemical cell.

FIG. 16 is a flow chart of a method for evaluating cost functions, according to an embodiment.

FIG. 17 is a flow chart of another method for in-situ determination of a thermodynamic state of degradation of an electrochemical cell assembly, according to an embodiment.

FIG. 18 is a graph of voltage versus capacity illustrating one example of an extracted voltage profile including an average of (i) voltage of the FIG. 1 electrochemical cell assembly during charging and (ii) voltage of the FIG. 1 electrochemical cell assembly during discharging.

FIG. 19 is a table illustrating one example of a differential profile generated in the FIG. 17 method.

FIG. 20 is a table illustrating another example of a differential profile generated in the FIG. 17 method.

FIG. 21 is a schematic diagram of an embodiment of the FIG. 1 electrical environment where a power converter is embodied by an inverter.

FIG. 22 is a schematic diagram of an embodiment of the FIG. 1 electrical environment where a power converter is embodied by a direct-current-to-direct-current (DC-to-DC) converter.

FIG. 23 is a schematic diagram of an electrical environment including a plurality of battery management system (BMS) nodes and a controller configured to determine thermodynamic state of degradation of respective electrochemical cell assemblies of the plurality of BMS nodes, according to an embodiment.

FIG. 24 is a schematic diagram of an alternate embodiment of the FIG. 23 electrical environment including a plurality of BMS nodes electrically coupled in parallel.

FIG. 25 is an illustration of an electric vehicle including an instance of a battery management system (BMS) node of FIG. 1 and an instance of the controller of FIG. 1.

FIG. 26 is an illustration of a battery energy storage system (BES) including an instance of the BMS node of FIG. 1 and an instance of the controller of FIG. 1.

FIG. 27 is an illustration of a consumer electronic device including an instance of the BMS node of FIG. 1 and an instance of the controller of FIG. 1.

### DETAILED DESCRIPTION OF THE EMBODIMENTS

One type of degradation of an electrochemical cell is thermodynamic degradation of the electrochemical cell. Symptoms of thermodynamic degradation of a Lithium-ion (Li-ion) electrochemical cell include, for example, (a) loss of active material from a positive electrode (LAM_{PE}) of the electrochemical cell, (b) loss of active material from a negative electrode (LAM_{NE}) of the electrochemical cell, and (c) loss of Lithium inventory (LLI) in the electrochemical cell. Accordingly, thermodynamic state of degradation (SOD) of an electrochemical cell may be expressed as a vector including one or more of LAM_{PE}, LAM_{NE}, and LLI. It is often desirable to determine SOD of an electrochemical cell in-situ, i.e., when the electrochemical cell is deployed in its intended application, such as when (i) the electrochemical cell is installed in an electric vehicle, (ii) the electrochemical cell is installed in a battery energy storage system, or (iii) the electrochemical cell is installed in a consumer electronic device. For example, in-situ determination of SOD of an electrochemical cell may enable early detection of electrochemical cell degradation by enabling SOD determination during normal operation of the electrochemical cell. Early detection of electrochemical cell degradation may enable corrective action to be performed on the electrochemical cell to limit further degradation of the electrochemical cell, or to even reverse some or all of the degradation of the electrochemical cell. Limiting or reversing degradation of an electrochemical cell, in turn, may extend the life of the electrochemical cell, improve performance of the electrochemical cell, and/or improve safety of the electrochemical cell. Additionally, early detection of electrochemical cell degradation may enable preemptive replacement of the electrochemical cell, i.e. replacement of the electrochemical cell before it fails, thereby preventing potential downtime and/or safety risks associated with electrochemical cell failure.

SOD of an electrochemical cell may be estimated using differential capacity (dQ/dV) analysis which includes using a low magnitude, e.g., C/20 or C/50, constant current to charge and discharge a full electrochemical cell while measuring full-cell voltage, where C refers to charge rate of the electrochemical cell and is equal to magnitude of current that the electrochemical cell can deliver while transitioning from a completely charged state to a completely discharged state over one hour. A measured full-cell dQ/dV profile is subsequently generated from the measured full-cell voltage. The charge and discharge process may require a long time period, e.g., approximately 100 hundred hours, to complete. The long time period required for dQ/dV analysis makes it frequently infeasible for use in determining SOD of an electrochemical cell in-situ. For example, it would typically be infeasible to take electrochemical cells of an electric vehicle or a battery energy storage system offline for approximately 100 hours to perform dQ/dV analysis.

Disclosed herein are systems and methods for in-situ determination of a thermodynamic SOD of an electrochemical cell assembly which significantly advance the state of the art of electrochemical cell monitoring. Particular embodiments are capable of determining SOD of an electrochemical cell assembly solely from data gathered during normal operation of the electrochemical cell assembly, such as data gathered during normal operation over an extended period. Consequently, these embodiments advantageously enable determination of thermodynamic SOD without disrupting operation of an electric vehicle, battery energy storage system, consumer electronic device, or other device where the electrochemical cell assembly is deployed. Additionally, certain embodiments supplement the data gathered during normal operation with data gathered during a slow charge or discharge of the electrochemical cell assembly, to enhance accuracy of thermodynamic SOD determination. Furthermore, particular embodiments promote rapid and accurate SOD determination through advantageous use of cost functions to minimize a difference between a model of the electrochemical cell assembly and field data collected from the electrochemical cell assembly. Accordingly, the new systems and methods may enable determination of thermodynamic SOD in applications that would not be feasible using conventional techniques.

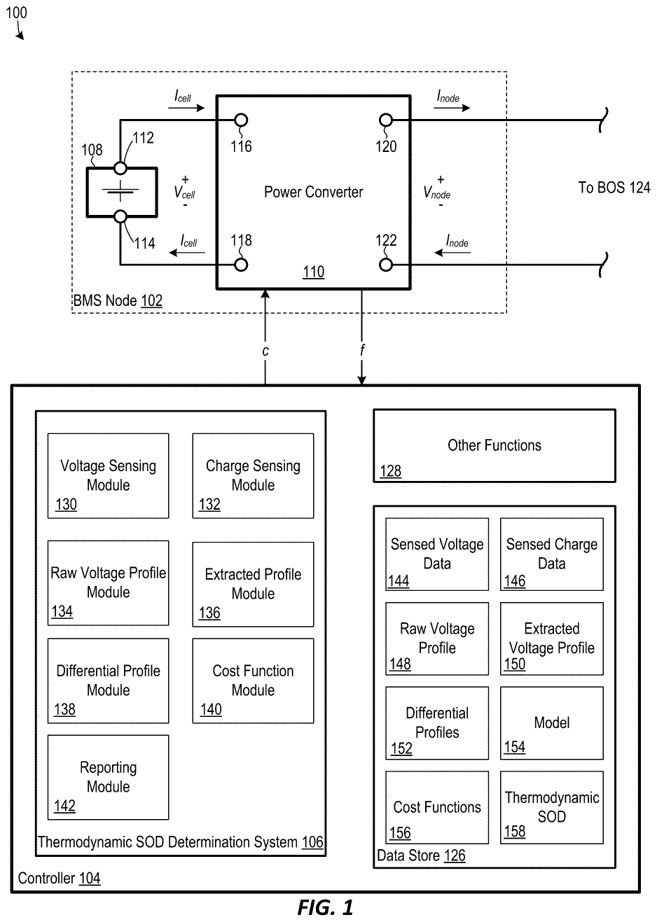

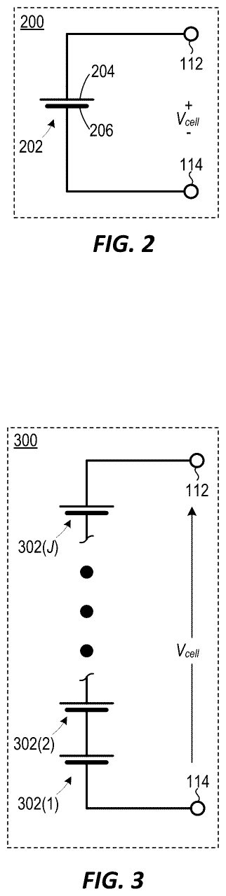

FIG. 1 is a schematic diagram of an electrical environment 100 including a battery management system (BMS) node 102 and a controller 104, where controller 104 includes a thermodynamic SOD determination system 106, and thermodynamic SOD determination system 106 is one embodiment of the new systems for determining thermodynamic SOD of an electrochemical cell assembly. BMS node 102 includes an electrochemical cell assembly 108 and a power converter 110. Electrochemical cell assembly 108 includes one or more electrochemical cells electrically coupled between a positive cell port 112 and a negative cell port 114. FIGS. 2-5, discussed below, illustrate several example embodiments of electrochemical cell assembly 108, although it is understood that electrochemical cell assembly 108 is not limited to the example embodiments of FIGS. 2-5.

FIG. 2 is a schematic diagram of an electrochemical cell assembly 200, which is an example embodiment of electrochemical cell assembly 108. Electrochemical cell assembly 200 includes a single electrochemical cell 202 electrically coupled between positive cell port 112 and negative cell port 114. Electrochemical cell 202 includes a positive electrode 204 and a negative electrode 206. In some embodiments, electrochemical cell 202 is a Li-ion electrochemical cell, such as a Li-ion electrochemical cell where negative electrode 206 includes a carbon-based material, such as graphite, although negative electrode 206 could be formed of other materials.

FIG. 3 is a schematic diagram of an electrochemical cell assembly 300, which is another example embodiment of electrochemical cell assembly 108. Electrochemical cell assembly 300 includes J electrochemical cells 302 electrically coupled in a series string between positive cell port 112 and negative cell port 114, where J is an integer greater than one. In this document, specific instances of an item may be referred to by use of a numeral in parentheses (e.g. electrochemical cell 302(1)) while numerals without parentheses refer to any such item (e.g. electrochemical cells 302). Positive and negative electrodes of electrochemical cells 302 are not labeled for illustrative clarity. In some embodiments, each electrochemical cell 302 is an instance of electrochemical cell 202 of FIG. 2.

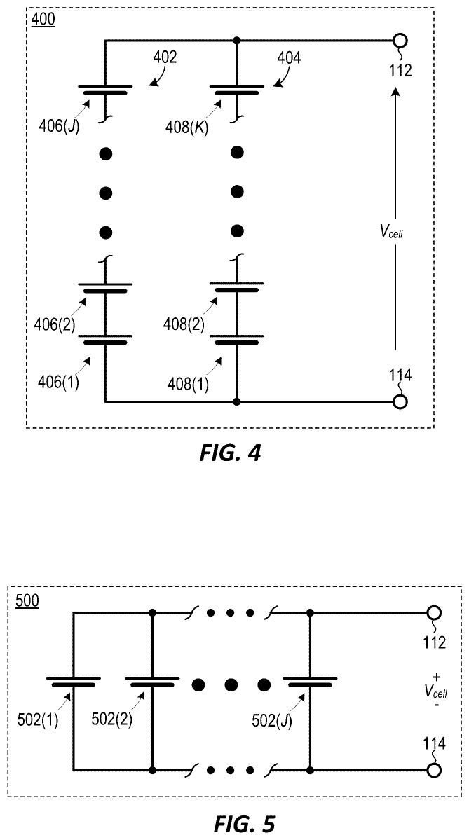

FIG. 4 is a schematic diagram of an electrochemical cell assembly 400, which is another example embodiment of electrochemical cell assembly 108. Electrochemical cell assembly 400 includes a first string 402 and a second string 404 electrically coupled in parallel within electrochemical cell assembly 400. String 402 includes J electrochemical cells 406 electrically coupled in series between positive cell port 112 and negative cell port 114, and string 404 includes K electrochemical cells 408 electrically coupled in series between positive cell port 112 and negative cell port 114. Each of J and K is an integer greater than one, and while not required, it is anticipated that K will normally be equal to J. Positive and negative electrodes of electrochemical cells 406 and 408 are not labeled for illustrative clarity. In some embodiments, each electrochemical cell 406 and 408 is an instance of electrochemical cell 202 of FIG. 2. Electrochemical cell assembly 400 could be modified to include one or more additional strings of series-coupled electrochemical cells. Additionally, electrochemical cell assembly 400 could be modified to include one or more additional electrochemical cells electrically coupled in parallel with one or more electrochemical cell 406 and/or one or more electrochemical cell 408.

FIG. 5 is a schematic diagram of an electrochemical cell assembly 500, which is another example embodiment of electrochemical cell assembly 108. Electrochemical cell assembly 500 includes J electrochemical cells 502 electrically coupled in parallel between positive cell port 112 and negative cell port 114, where J is an integer greater than one. In certain embodiments, each electrochemical cell 502 is a Li-ion electrochemical cell. Positive and negative electrodes of electrochemical cells 502 are not labeled for illustrative clarity. In some embodiments, each electrochemical cell 502 is an instance of electrochemical cell 202 of FIG. 2.

Referring again to FIG. 1, power converter 110 includes two input ports 116 and 118 and two output ports 120 and 122. Power converter 110 is electrically coupled to electrochemical cell assembly 108 via input ports 116 and 118, and power converter 110 is electrically coupled to a balance of system (BOS) 124 (not shown) via output ports 120 and 122. Balance of system 124 includes, for example, one or more additional BMS nodes, a load, an energy source, switches, and/or one or more other power converters (e.g., an inverter and/or a direct-current-to-direct-current (DC-to-DC) converter). In some embodiments, BMS node 102 is installed in an electric vehicle, a battery energy storage system connected to an electric power grid, a consumer electronic device, or other system or device.

Power converter 110 is configured to convert a voltage V_{cell} across electrochemical cell assembly 108 to a voltage V_{node} across output ports 120 and 122 (or vice versa). Additionally, power converter 110 is configured to convert a current I_{cell} flowing through electrochemical cell assembly 108 to a current I_{node} flowing between output ports 120 and 122 (or vice versa). Power converter 110 is at least partially controlled by controller 104 via control signals c from controller 104, as discussed below. Additionally, power converter 110 may be partially controlled by one or more one additional controllers (not shown). Power converter 110 is also configured to provide feedback signals f to controller 104, where feedback signals f represent one or more parameters of BMS node 102. Examples of possible parameters represented by feedback signals f include one or more of voltage V_{cell}, current I_{cell}, voltage V_{node}, current I_{node}, and temperature of electrochemical cell assembly 108. Control signals c and feedback signals f are communicatively coupled between power converter 110 and controller 104, for example, via one or more electrical communication links (not shown), one or more optical communication links (e.g., an optical cable communication link or a free space optical communication link) (not shown), and/or one more radio frequency (RF) communications links (e.g., a waveguide RF communication link or a free space RF communication link) (not shown).

Power converter 110 is, for example, DC-to-DC converter or an inverter. In some embodiments, power converter 110 includes one or more of a boost converter, a buck converter, a buck-boost converter, a buck and boost converter, a flyback converter, a forward converter, a full bridge converter, a half bridge converter, a linear regulator, a Cúk converter, a resonant converter, or a switched capacitor converter. In certain embodiments, power converter 110 includes two or more power converters electrically coupled in series and/or in parallel. Certain embodiments of power converter 110 are galvanically isolated, e.g., input ports 116 and 118 are galvanically isolated from output ports 120 and 122. In some other embodiments, power converter 110 is non-isolating. Additionally, in certain embodiments, each of input port 116, input port 118, output port 120, and output port 122 is part of a different respective electrical node, while in some other embodiments, at least two of the aforementioned ports are part of a common electrical node. For example, in certain embodiments, input port 118 and output port 122 are part of a common electrical node, such as a reference node. In certain alternate embodiments, power converter 110 is replaced with one or more switches (not shown), where each switch is configured to selectively electrically couple two or more of input port 116, input port 118, output port 120, and output port 122 to each other, such as to selectively electrically couple electrochemical cell assembly 108 to BOS 124. In such alternate embodiments, BMS node 102 is not capable of regulating magnitude of voltage or current.

Controller 104 includes a data store 126 and other functions 128 in addition to thermodynamic SOD determination system 106. Thermodynamic SOD determination system 106 includes a voltage sensing module 130, a charge sensing module 132, a raw voltage profile module 134, an extracted profile module 136, an optional differential profile module 138, a cost function module 140, and a reporting module 142. Data store 126 includes sensed voltage data 144, sensed charge data 146, a raw voltage profile 148, an extracted voltage profile 150, one or more optional differential profiles 152, a model 154 of electrochemical cell assembly 108, one or more cost functions 156, and thermodynamic SOD 158.

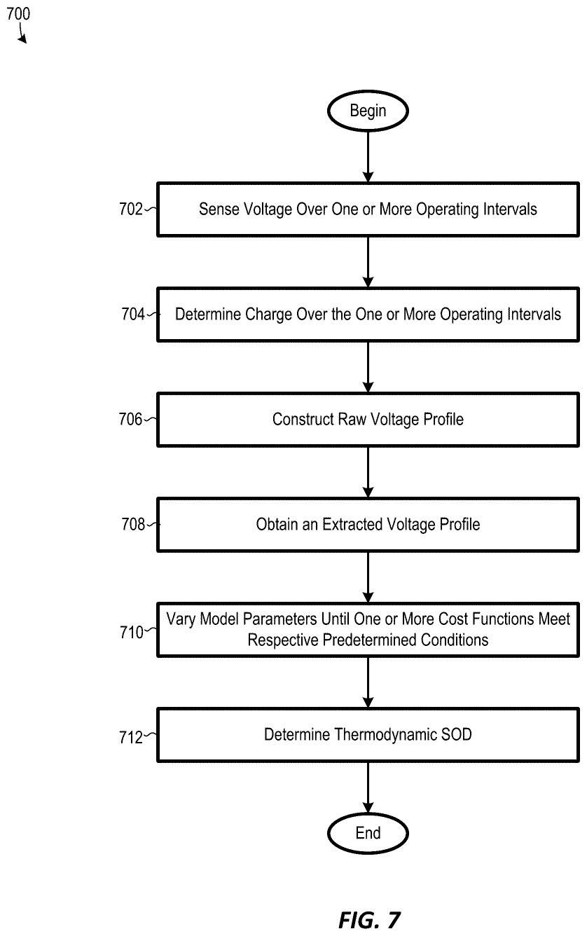

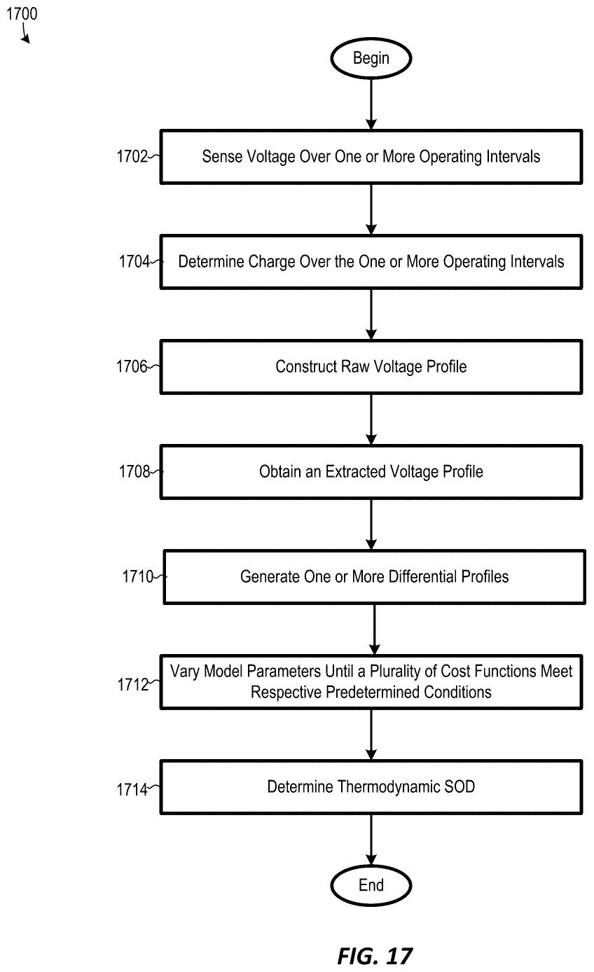

The following is a brief summary of operation of the modules of Thermodynamic SOD determination system 106. Detailed examples of operation of Thermodynamic SOD determination system 106 are discussed below with respect to FIGS. 7 and 17, although it is understood that Thermodynamic SOD determination system 106 is not limited to operating according to the example methods of FIG. 7 and FIG. 17.
(1) Voltage sensing module 130 is configured to sense V_{cell} across electrochemical cell assembly 108 to generate sensed voltage data 144, such as from measurements of V_{cell} generated by voltage sensing circuitry (not shown) of power converter 110 and transmitted to controller 104 via feedback signals f.
(2) Charge sensing module 132 is configured to determine charge flowing between electrochemical cell assembly 108 and external circuitry to generate sensed charge data 146 representing capacity of electrochemical cell assembly 108 as a function of time, where capacity of electrochemical cell assembly 108 is quantity of charge stored in electrochemical cell assembly 108, such as expressed in Coulombs. In some embodiments, charge sensing module 132 is configured to determine sensed charge data 146 via feedback signals f generated by a Coulomb counter (not shown) of power converter 110.
(3) Raw voltage profile module 134 is configured to construct raw voltage profile 148 from each of sensed voltage data 144 and sensed charge data 146, where raw voltage profile 148 represents voltage V_{cell} as a function of capacity of electrochemical cell assembly 108.
(4) Extracted profile module 136 is configured to generate extracted voltage profile 150 by extracting a subset of raw voltage profile 148, where extracted voltage profile 150 includes a plurality of open circuit voltage values of electrochemical cell assembly 108.
(5) Optional differential profile module 138, when present in thermodynamic SOD determination system 106, is configured to generate one or more differential profiles 152 of electrochemical cell assembly 108. The one or more differential profiles 152 of electrochemical cell assembly 108 include at least one of (i) a differential charge profile representing change in capacity electrochemical cell assembly 108 with respect to change in voltage V_{cell}, as a function of capacity of the electrochemical cell assembly 108 and (ii) a differential voltage profile representing change in voltage V_{cell}, with respect to change in capacity of electrochemical cell assembly 108, as a function of capacity of electrochemical cell assembly 108.
(6) Cost function module 140 is configured to vary parameters of model 154 of electrochemical cell assembly 108 until one or more cost functions 156 meet respective predetermined conditions. Each cost function 156 represents error in model 154 of the electrochemical cell assembly 108, for example, with respect to one or more of (i) data associated with extracted voltage profile 150 and (ii) data associated with one or more of differential profiles 152.
(7) Reporting module 142 is configured to determine thermodynamic SOD 158 of electrochemical cell assembly 108 at least partially based on parameters of a final iteration of model 154 of electrochemical cell assembly 108. In some embodiments, thermodynamic SOD 158 of electrochemical cell assembly 108 is vector expressing one or more of LAM_{PE}, LAM_{NE}, and LLI from final parameters of model 154.

Other functions 128 are configured to control power converter 110 via control signals c to control charging and discharging of electrochemical cell assembly 108 for purposes other than SOD estimation, such as to control charging and discharging of electrochemical cell assembly 108 during normal operation of electrochemical cell assembly 108. Other functions 128 could be omitted from controller 104, and in such case, one or more additional controllers (not shown) may take the place of other functions 128.

The elements of controller 104 need not be co-packaged or co-located. For example, in certain embodiments, some elements of controller 104 are located in or near BMS node 102, while other elements of controller 104 are remotely located from BMS node 102. The remotely located elements could be embodied, for example, by a central controller for multiple BMS nodes, or by a controller implemented in a distributed computing system, e.g., in a cloud computing system. While controller 104 is depicted as being separate from BMS node 102, controller 104 could instead be partially or fully integrated in BMS node 102.

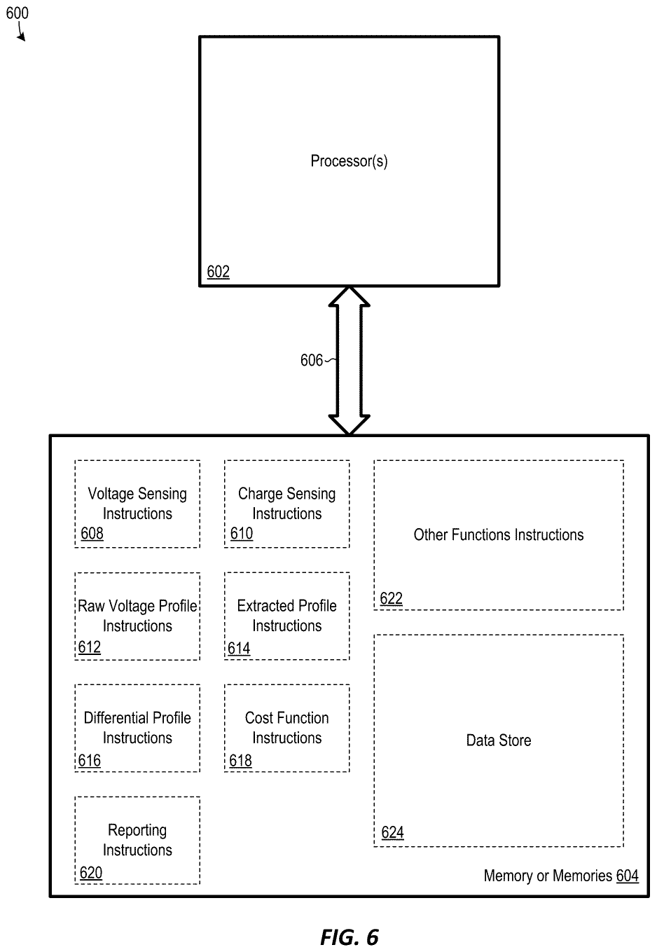

The elements of controller 104 are implemented, for example, by analog and/or digital electronic circuitry. In some embodiments, one or more elements of controller 104 are at least partially implemented by one or more processors executing non-transitory instructions, such as software and/or firmware, stored in one or more memories or other storage elements. For example, FIG. 6 is a block diagram of a controller 600, which is one possible embodiment of controller 104, although it is understood that controller 104 is not limited to the FIG. 6 embodiment. Controller 600 includes one or more processors 602, henceforth referred to as “processors 602” for brevity, and one or more memories 604, henceforth referred to “memories 604” for brevity. Processors 602 are communicatively coupled to memories 604, as symbolically shown by an arrow 606. Processors 602 and memories 604 may be co-packaged, e.g., on a single circuit board or in a single integrated circuit, or they may be separated from each other. Additionally, in embodiments where processors 602 include a plurality of processors, the plurality of processors need not be co-located but instead could be implemented in a distributed computing environment. Similarly, in embodiments where memories 604 include a plurality of memories, the plurality of memories need not be co-located but instead could be implemented in a distributed storage environment.

Memories 604 include the following stored therein: voltage sensing instructions 608, charge sensing instructions 610, raw voltage profile instructions 612, extracted profile instructions 614, differential profile instructions 616, cost function instructions 618, and reporting instructions 620, where each of the aforesaid instructions is, for example, software and/or firmware. Processors 602 are configured to execute voltage sensing instructions 608, charge sensing instructions 610, raw voltage profile instructions 612, extracted profile instructions 614, differential profile instructions 616, cost function instructions 618, and reporting instructions 620 to perform the functions of voltage sensing module 130, charge sensing module 132, raw voltage profile module 134, extracted profile module 136, differential profile module 138, cost function module 140, and reporting module 142, respectively. Additionally, processors 602 are configured to execute other functions instructions 622, which are, for example, software and/or firmware, to perform other functions 128. Data store 624 is an embodiment of data store 126 (FIG. 1), but contents of data store 624 are not shown in FIG. 6 for illustrative clarity.

FIG. 7 is a flow chart of a method 700 for in-situ determination of a thermodynamic state of degradation of an electrochemical cell assembly, and method 700 is one example of a method performed by thermodynamic SOD determination system 106. However, method 700 could be adapted for execution by a SOD determination system other than thermodynamic SOD determination system 106.

In a block 702 of method 700, voltage sensing module 130 senses voltage V_{cell} of electrochemical cell assembly 108 in-situ, i.e., when it is deployed in its intended application, over one or more operating intervals of electrochemical cell assembly 108 to generate sensed voltage data 144. The one or more operating intervals of electrochemical cell assembly 108 may include (i) one or more charging intervals of electrochemical cell assembly 108 where energy is transferred to electrochemical cell assembly 108 from an energy source and (ii) one or more discharging intervals of electrochemical cell assembly 108 where energy stored in electrochemical cell assembly 108 is discharged into a load. In some embodiments, the one or more operating intervals collectively span a significant period of time, such as days, weeks, months, or even longer. As such, sensed voltage data 144 may represent voltage V_{cell} over a long period of time. Additionally, the one or more operating intervals may include a plurality of operating intervals that need not be contiguous. For example, in some embodiments, two or more consecutive operating intervals may be separated by an idle interval where electrochemical cell assembly 108 is neither being charged nor discharged.

Furthermore, a charging interval of electrochemical cell assembly 108 need not require that electrochemical cell assembly 108 transition from zero state of charge to 100 percent state of charge. For example, electrochemical cell assembly 108 could transition from 10 percent state of charge to 90 percent state of charge during a charging interval. Similarly, a discharging interval of electrochemical cell assembly 108 need not require that electrochemical cell assembly 108 transition from 100 percent state of charge to zero state of charge. For example, electrochemical cell assembly 108 could transition from 89 percent state of charge to 7 percent state of charge during a discharging interval.

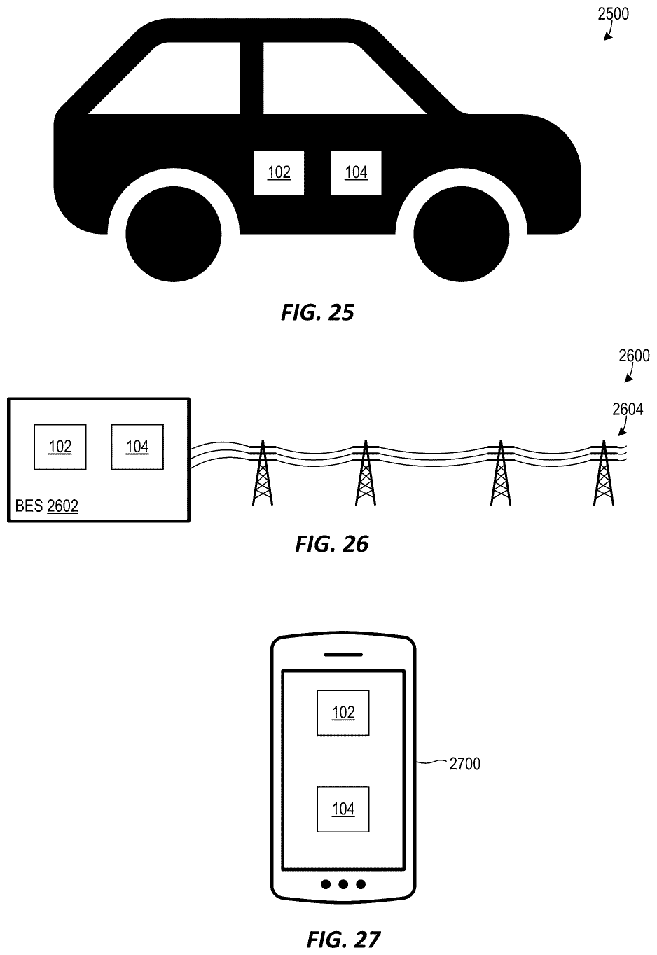

It should be noted that the fact that voltage sensing module 130 senses voltage V_{cell} of electrochemical cell assembly 108 in-situ in block 702 enables particular embodiments of voltage sensing module 130 to execute block 702 without interfering with normal operation of electrochemical cell assembly 108. For example, assume that electrochemical cell assembly 108 is part of an electric vehicle, such as discussed below with respect to FIG. 25. In this example, voltage sensing module 130 may perform block 702 over a period of normal operation of the electric vehicle, e.g., during normal driving of the electric vehicle and during normal idle periods of the electric vehicle, such that execution of block 702 does not interfere with normal operation of the electric vehicle. As another example, assume that electrochemical cell assembly 108 is part of a battery energy storage system connected to an electric power grid, such as discussed below with respect to FIG. 26. In this example, voltage sensing module 130 may perform block 702 over a period of normal operation of the battery energy storage system, e.g., during normal charging of the battery energy storage system from the electric power grid and normal discharging of the battery energy storage system into the electric power grid, as well as during normal idle periods of the battery energy storage system, such that execution of block 702 does not interfere with normal operation of the battery energy storage system. As a further example, assume that electrochemical cell assembly 108 is part of a consumer electronic device, such as discussed below with respect to FIG. 27. In this example, voltage sensing module 130 may perform block 702 over a period of normal operation of the consumer electronic device, e.g., during normal charging of the consumer electronic device, during normal operation of the consumer electronic device, and during normal idle periods of the consumer electronic device, such that execution of block 702 does not interfere with normal operation of the consumer electronic device.

Importantly, the one or more operating intervals of block 702 must include a plurality, e.g., three or more, rest operating states of electrochemical cell assembly 108, where each rest operating state occurs at a different respective capacity of electrochemical cell assembly 108. In certain embodiments, electrochemical cell assembly 108 operates in a rest state when magnitude of current I_{cell} is zero. In certain other embodiments, electrochemical cell assembly 108 operates in rest state when magnitude of current I_{cell} is less than a predetermined maximum rest current value. The maximum rest current value is, for example, a predetermined percentage of a maximum rated value of current I_{cell}, such as five percent, one percent, one tenth of a percent, etc., of the maximum rate value of current I_{cell}. Values of voltage V_{cell} when electrochemical cell assembly 108 is in a rest operating state are referred to as open circuit voltage values of electrochemical cell assembly 108. In certain embodiments, other functions 128 of controller 104 control operation of electrochemical cell assembly 108 by controlling power converter 110 to ensure that electrochemical cell assembly 108 operates in a rest operating state at a plurality of different times over one or more operating intervals of electrochemical cell assembly 108. In certain embodiments, voltage sensing module 130 also tracks, for each of the time periods where electrochemical cell assembly 108 is at rest, whether electrochemical cell assembly 108 was operating in a charging operating mode or in a discharging operating mode immediately before the time period where electrochemical cell assembly 108 is at rest.

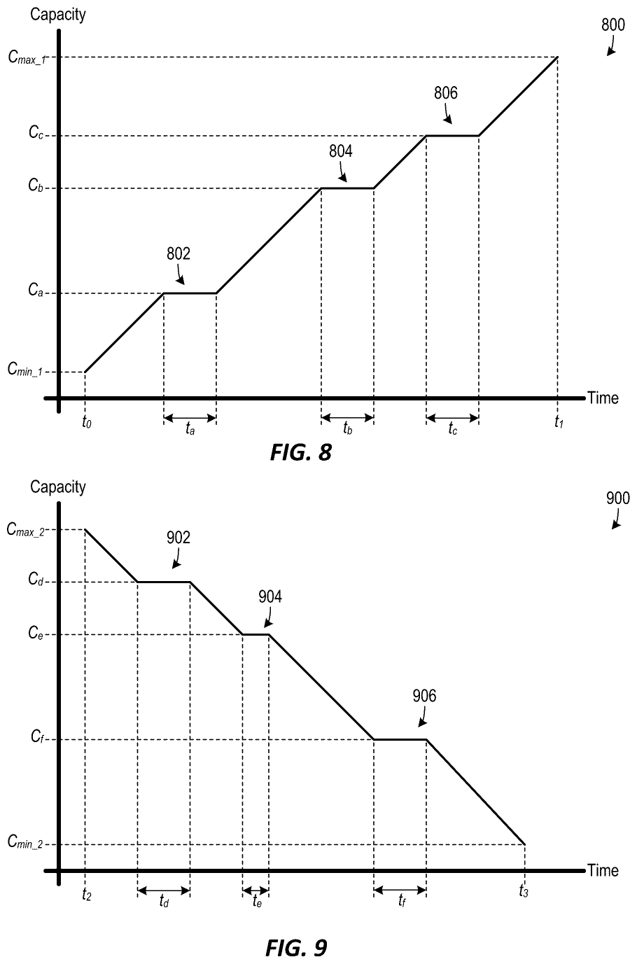

FIG. 8 is a graph of capacity versus time illustrating one example of implementing rest operating states during a charging interval 800 of electrochemical cell assembly 108. It is understood, though, that charging intervals of electrochemical cell assembly 108, as well as rest operating states implemented during a charging interval, are not limited to the FIG. 8 example. Electrochemical cell assembly 108 is charged from a capacity C_{min_1} to a capacity C_{max_1} during a time period ranging from t₀ to t₁, in charging interval 800. Charging interval 800 includes a rest operating state 802, a rest operating state 804, and a rest operating state 806, where charging of electrochemical cell assembly 108 is paused and magnitude of current I_{cell} is either zero or is less than a predetermined maximum rest current value. Electrochemical cell assembly 108 operates in rest operating state 802 during a time period ta, and electrochemical cell assembly 108 has a capacity of Cₐ during rest operating state 802. Additionally, electrochemical cell assembly 108 operates in rest operating state 804 during a time period tb, and electrochemical cell assembly 108 has a capacity of C_{b} during rest operating state 804. Furthermore, electrochemical cell assembly 108 operates in rest operating state 806 during a time period t_{c}, and electrochemical cell assembly 108 has a capacity of C_{c} during rest operating state 806. Each of capacities Cₐ, C_{b}, and C_{c} is different from each other of Cₐ, C_{b}, and C_{c}, and capacity of electrochemical cell assembly 108 therefore differs between each of rest operating state 802, rest operating state 804, and rest operating state 806. Electrochemical cell assembly 108 operates in a charge operating state between time t₀ and time t₁ when electrochemical cell assembly 108 is not operating in rest operating state 802, 804, or 806.

FIG. 9 is a graph of capacity versus time illustrating one example of implementing rest operating states during an example discharging interval 900 of electrochemical cell assembly 108. It is understood, though, that discharging intervals of electrochemical cell assembly 108, as well as rest operating states implemented during a discharging interval, are not limited to the FIG. 9 example. Electrochemical cell assembly 108 is discharged from a capacity C_{max_2} to a capacity C_{min_2} during a time period ranging from t₂ to t₃, in discharging interval 900 of FIG. 9. Discharging interval 900 includes three rest operating state 902, 904, and 906, where discharging of electrochemical cell assembly 108 is paused and magnitude of current I_{cell} is either zero or is less than a predetermined maximum rest current value. Electrochemical cell assembly 108 operates in rest operating state 902 during a time period t₂, and electrochemical cell assembly 108 has a capacity of C_{d} during rest operating state 902. Additionally, electrochemical cell assembly 108 operates in rest operating state 904 during a time period tₑ, and electrochemical cell assembly 108 has a capacity of Cₑ during rest operating state 904. Furthermore, electrochemical cell assembly 108 operates in rest operating state 906 during a time period t_{f}, and electrochemical cell assembly 108 has a capacity of C_{f} during rest operating state 906. Each of capacities C_{d}, Cₑ, and C_{f} is different from each other of C_{d}, Cₑ, and C_{f}, and capacity of electrochemical cell assembly 108 therefore differs between each of rest operating state 902, rest operating state 904, and rest operating state 906. Electrochemical cell assembly 108 operates in a discharge operating state between time t₂ and time t₃ when electrochemical cell assembly 108 is not operating in rest operating state 902, 904, or 906.

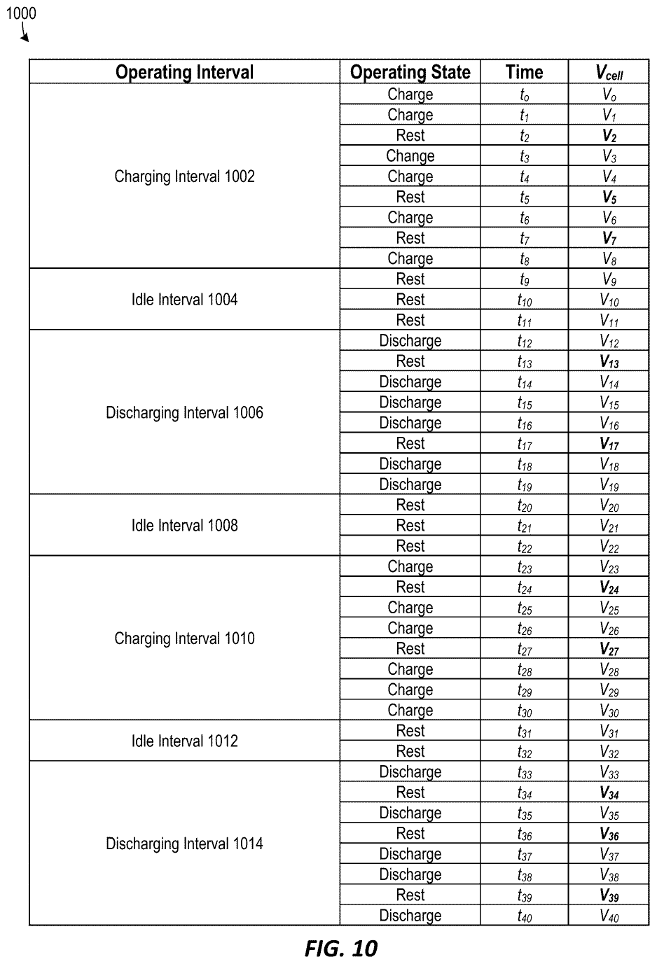

FIG. 10 is a table illustrating sensed voltage data 1000, where sensed voltage data 1000 is one example of sensed voltage data 144 from block 702 of FIG. 7. It is understood, though, that sensed voltage data 144 is not limited to the example of FIG. 10. For example, sensed voltage data 144 may be sensed over a different quantity of operating intervals than that illustrated in FIG. 10. As another example, sensed voltage data 144 may be sensed over solely charging intervals or over solely discharging intervals, instead of over each of charging intervals, idle intervals, and discharging intervals, as illustrated in FIG. 10.

Sensed voltage data 1000 includes sensed values of voltage V_{cell} equal to V₀ through V₄₀ at respective times t₀ through t₄₀, which collectively span a charging interval 1002, an idle interval 1004, a discharging interval 1006, an idle interval 1008, a charging interval 1010, an idle interval 1012, and a discharging interval 1014. For example, sensed voltage data 1000 includes a value of voltage V_{cell} equal to V₀ at a time t₀, a value of voltage V_{cell} equal to V₁ at time t₁, and so on, from charging interval 1002. As another example, sensed voltage data 1000 includes a value of voltage V_{cell} equal to V₉ at time t₉, a value of voltage V_{cell} equal to V₁₀ at a time t₁₀, and a value of voltage V_{cell} equal to V₁₁ at a time t₁₁, from idle interval 1004. Each charging interval 1002 and 1010 includes time periods where electrochemical cell assembly 108 is operating in a rest operating state as well as time periods where electrochemical cell assembly 108 is operating in a charge operating state. Additionally, each discharging interval 1006 and 1014 includes time periods where electrochemical cell assembly 108 is operating in a rest operating state as well as time periods where electrochemical cell assembly 108 is operating in a discharge operating state. Electrochemical cell assembly continuously operates in a rest operating state during each idle interval 1004, 1008, and 1012. Values of voltage V_{cell} that are shown in bold type in FIG. 10 are open circuit voltage values of voltage V_{cell}. Specifically, values V₂, V₅, V₇, V₁₃, V₁₇, V₂₄, V₂₇, V₃₄, V₃₆, and V₃₉ are open circuit voltage values of voltage V_{cell}. Open circuit voltage values V₂, V₅, V₇, V₂₄, and V₂₇ correspond to electrochemical cell assembly 108 operating in a rest operating state during a charging operating interval 1002 or 1010, and open circuit voltage values V₁₃, V₁₇, V₃₄, V₃₆, and V₃₉ correspond to electrochemical cell assembly 108 operating in a rest operating state during a discharging operating interval 1006 or 1014. The quantity and timing of open circuit voltage values may vary, such as according to operating conditions of electrochemical cell assembly 108, the application of electrochemical cell assembly 108, and/or charging or discharging algorithms implemented by power converter 110 under the control of other functions 128 of controller 104. Additionally, while sensed voltage data 1000 includes a relatively small quantity of values of voltage V_{cell} from each operating interval due to space constraints in FIG. 10, sensed voltage data 144 can, and typically will, include a large quantity of values of voltage V_{cell}, e.g., one value for each minute, one value for each 30 seconds, one value for each second, etc., over each operating interval.

Referring again to FIG. 7, method 700 proceeds from block 702 to a block 704 where charge sensing module 132 determines charge flowing between electrochemical cell assembly 108 and external circuitry over the same one or more operating interval of electrochemical cell assembly 108 from block 702, to generate sensed charge data 146. For example, in some embodiments, power converter 110 includes a Coulomb counter (not shown) that tracks charge flowing between electrochemical cell assembly 108 and external circuitry (e.g., power converter 110), such as from sensed values of current I_{cell}, (ii) power converter 110 provides tracked charge values from the Coulomb counter to charge sensing module 132 via feedback signals f, and (ii) charge sensing module 132 generates sensed charge data 146 representing capacity of electrochemical cell assembly 108 as a function of time.

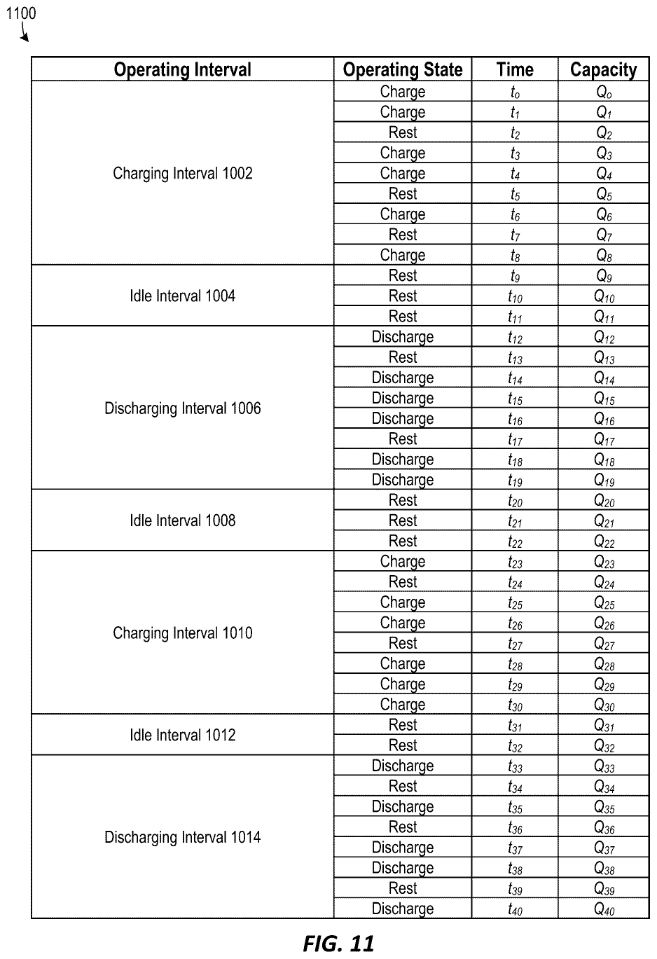

FIG. 11 is a table illustrating sensed charge data 1100, where sensed charge data 1100 is one example of sensed charge data 146 from block 704 of FIG. 7. It is understood, though, that sensed charge data 146 is not limited to the example of FIG. 11. Sensed charge data 1100 includes sensed values of capacity Q equal to Q₀ through Q₄₀ at respective times to through t₄₀, where times t₀ through t₄₀ of FIG. 11 are the same as times to through t₄₀ of FIG. 10. Accordingly, the values of capacity Q of sensed charge data 1100 collectively span the same operating intervals and operating states as FIG. 10, i.e., charging interval 1002 including charge and rest operating states, idle interval 1004 including rest operating states, discharging interval 1006 including discharge and rest operating states, idle interval 1008 including rest operating states, charging interval 1010 including charge and rest operating states, idle interval 1012 including rest operating states, and discharging interval 1014 including discharge and rest operating states. For example, sensed charge data 1100 includes a value of capacity Q equal to Q₀ at a time t₀, a value of capacity Q equal to Q₁ at time t₁, and so on, from charging interval 1002. As another example, sensed charge data 1100 includes a value of capacity Q equal to Q₉ at time t₉, a value of capacity Q equal to Q₁₀ at a time t₁₀, and a value of capacity Q equal to Q₁₁ at a time t₁₁, from idle interval 1004. While sensed charge data 1100 includes a relatively small quantity of values of capacity Q from each operating interval due to space constraints in FIG. 11, sensed charge data 146 can, and typically will, include a large quantity of values of capacity Q, e.g., one value for each minute, one value for each 30 seconds, one value for each second, etc., over each operating interval.

Referring again to FIG. 7, method 700 proceeds from block 704 to a block 706 where raw voltage profile module 134 constructs raw voltage profile 148 from each of sensed voltage data 144 and sensed charge data 146, where raw voltage profile 148 represents voltage V_{cell} of electrochemical cell assembly 108 as a function of capacity of electrochemical cell assembly 108. For example, in certain embodiments, raw voltage profile module 134 determines from sensed charge data 146 and sensed voltage data 144 a respective capacity of electrochemical cell assembly 108 at each value of voltage V_{cell}, to construct raw voltage profile 148.

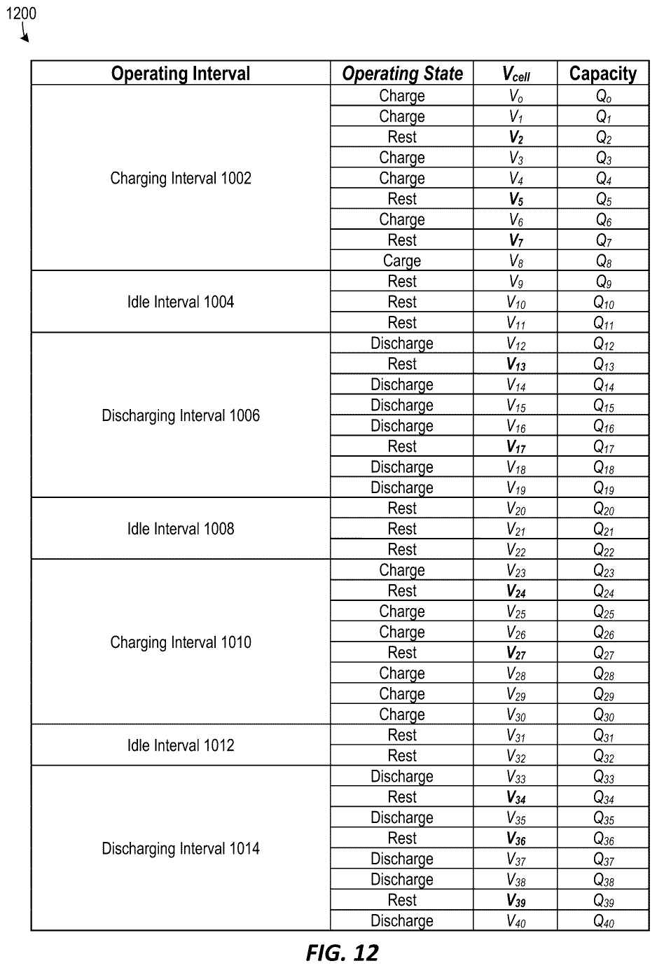

FIG. 12 is a table illustrating a raw voltage profile 1200, where raw voltage profile 1200 is one example of raw voltage profile 148 from block 706. Raw voltage profile 1200 is based on sensed voltage data 1000 of FIG. 10 and sensed charge data 1100 of FIG. 11. Raw voltage profile 1200 includes a respective value of capacity Q (from sensed charge data 1100) for each value of voltage V_{cell} (from sensed voltage data 1000). For example, raw voltage profile 1200 includes a value of capacity Q₀ corresponding to V_{cell} voltage V₀, a value of capacity Q₁ corresponding to V_{cell} voltage V₁, a value of capacity Q₂ corresponding to V_{cell} voltage V₂, and so on. Raw voltage profile 1200 spans the same operating intervals and operating states as sensed voltage data 1000 and sensed charge data 1100, i.e., charging interval 1002 including charge and rest operating states, idle interval 1004 including rest operating states, discharging interval 1006 including discharge and rest operating states, idle interval 1008 including rest operating states, charging interval 1010 including charge and rest operating states, idle interval 1012 including rest operating states, and discharging interval 1014 including discharge and rest operating states. Accordingly, raw voltage profile 1200 includes the same open circuit voltage values of voltage V_{cell} as sensed voltage data 1000 of FIG. 10; i.e., values V₂, V₅, V₇, V₁₃, V₁₇, V₂₄, V₂₇, V₃₄, V₃₆, and V₃₉, which are shown in bold type in FIG. 12.

Returning again to FIG. 7, method 700 proceeds from block 706 to a block 708 where extracted profile module 136 extracts a subset of raw voltage profile 148 constructed in block 706 to obtain extracted voltage profile 150, where extracted voltage profile 150 includes a plurality of open circuit voltage values of electrochemical cell assembly 108. Extracted voltage profile 150 represents voltage V_{cell} as a function of capacity of electrochemical cell assembly 108 during charging of electrochemical cell assembly 108, during discharging of electrochemical cell assembly 108, or during each of charging and discharging of electrochemical cell assembly 108, depending on the configuration of extracted profile module 136. It should be noted that the data of extracted voltage profile 150 need not be limited to data from a single operating interval of electrochemical cell assembly 108. Instead, the data of extracted voltage profile 150 may be obtained from a plurality of operating intervals of electrochemical cell assembly 108, such as to enable extracted voltage profile 150 to include a desired quantity of open circuit values of voltage V_{cell} and/or to increase the resolution of extracted voltage profile 150.

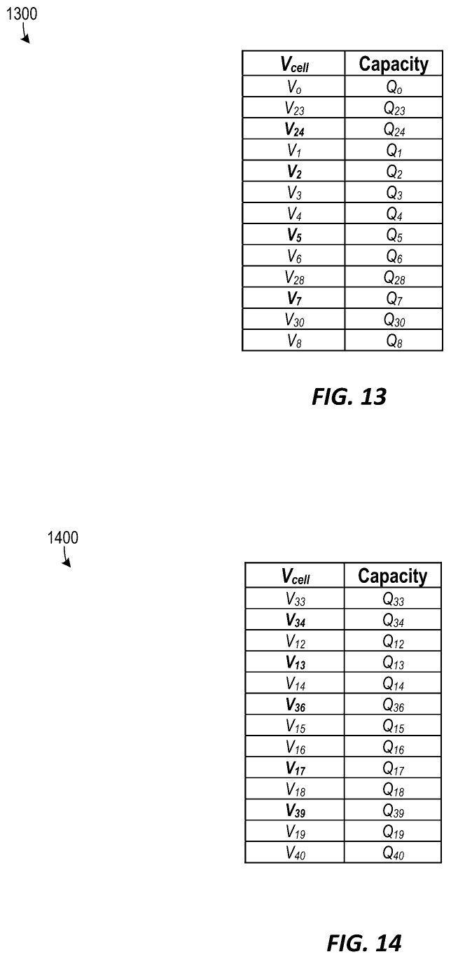

For example, FIG. 13 is a table illustrating an extracted voltage profile 1300, where extracted voltage profile 1300 is one example of extracted voltage profile 150 representing magnitude of voltage V_{cell} as a function of capacity during charging of electrochemical cell assembly 108. Extracted voltage profile 1300 includes data from each of charging interval 1002 and charging interval 1010. Specifically, extracted voltage profile 1300 (i) includes values of voltage V_{cell} at each of capacities Q₀, Q₁, Q₂, Q₃, Q₄, Q₅, Q₆, Q₇, and Q₈ from charging interval 1002, and (ii) extracted voltage profile 1300 includes values of voltage V_{cell} at each of capacities Q₂₃, Q₂₄, Q₂₈, and Q₃₀ from charging interval 1010. As such, extracted voltage profile 1300 includes a greater quantity of data than extracted voltage profile 1300 would if it were based solely on charging interval 1002 or solely on charging interval 1010, thereby promoting high resolution of extracted voltage profile 1300 and enabling extracted voltage profile 1300 to include additional open circuit values of voltage V_{cell}. Extracted voltage profile 1300 includes open circuit voltage values V₂₄, V₂, V₅, and V₇ (shown in bold type).

FIG. 14 is a table illustrating an extracted voltage profile 1400, where extracted voltage profile 1400 is one example of extracted voltage profile 150 during discharging of electrochemical cell assembly 108. Extracted voltage profile 1400 includes data from each of discharging interval 1006 and discharging interval 1014. Specifically, extracted voltage profile 1400 (i) includes values of voltage V_{cell} at each of capacities Q₁₂, Q₁₃, Q₁₄, Q₁₅, Q₁₆, Q₁₇, Q₁₈, and Q₁₉ from discharging interval 1006, and (ii) extracted voltage profile 1400 includes values of voltage V_{cell} at each of capacities Q₃₃, Q₃₄, Q₃₆, Q₃₉, and Q₄₀ from discharging interval 1014. As such, extracted voltage profile 1400 includes greater quantity of data than extracted voltage profile 1400 would if it were based solely on discharging interval 1006 or solely on discharging interval 1014, thereby promoting high resolution of extracted voltage profile 1400 and enabling extracted voltage profile 1400 to include additional open circuit values of voltage V_{cell}. Extracted voltage profile 1400 includes open circuit voltage values V₃₄, V₁₃, V₃₆, V₁₇, and V₃₉ (shown in bold type).

Referring again to FIG. 1, the one or more electrical chemical cells of electrochemical cell assembly 108 exhibit over-potential, which is a difference between (i) voltage V_{cell} when electrochemical cell assembly 108 is perturbated (undergoing charging or discharging) and (ii) voltage V_{cell} when electrochemical cell assembly 108 is at a ground state (not undergoing charging or discharging and fully relaxed), i.e., such as after electrochemical cell assembly 108 has operated in a rest state for a long period of time. Specifically, electrochemical cell assembly 108 exhibits positive over-potential while charging, i.e., magnitude of voltage V_{cell} while charging is greater than magnitude of voltage V_{cell} while electrochemical cell assembly 108 is in a ground state, at a given capacity of electrochemical cell assembly 108. Conversely, electrochemical cell assembly 108 exhibits negative over-potential while discharging, i.e., magnitude of voltage V_{cell} while discharging is less than magnitude of voltage V_{cell} while electrochemical cell assembly 108 is in a ground state, at a given capacity of electrochemical cell assembly 108.

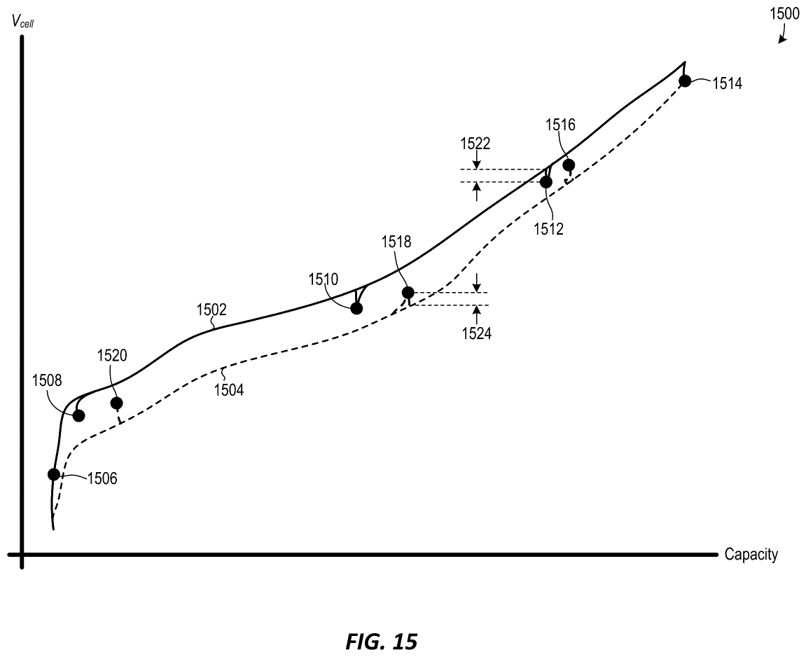

FIG. 15 is a graph 1500 of voltage V_{cell} versus capacity illustrating examples of over-potential of the embodiment of electrochemical cell assembly 108 illustrated in FIG. 2, which includes a single electrochemical cell 202. FIG. 15 includes a curve 1502 of voltage V_{cell} versus capacity during charging of electrochemical cell 202 as well as a curve 1504 of voltage V_{cell} versus capacity during discharging of electrochemical cell 202. FIG. 15 further includes (i) circles indicating open circuit voltage values 1508, 1510, 1512, and 1514 of voltage V_{cell} during charging of electrochemical cell 202 and (ii) circles indicating open circuit voltage values 1516, 1518, 1520, and 1506 of voltage V_{cell} during discharging of electrochemical cell 202. Electrochemical cell 202 exhibits over-potential over most of its operating range, illustrated in FIG. 15. For example, electrochemical cell 202 has a positive over-potential 1522 at open circuit voltage value 1512 during charging, and electrochemical cell 202 has a negative over-potential 1524 at open circuit voltage value 1518 during discharging. The over-potential exhibited by electrochemical cell 202 results in the hysteresis collectively exhibited by curve 1502 and curve 1504 in FIG. 15.

Referring again to FIGS. 1 and 7, significant time may be required for voltage V_{cell} to settle to an open circuit voltage value when electrochemical cell assembly 108 enters a rest operating state due to over-potential exhibited by the one or more electrochemical cells of electrochemical cell assembly 108. Therefore, in certain embodiments of block 708, extracted profile module 136 generates extracted voltage profile 150 such that each open circuit voltage value of voltage V_{cell} included in extracted voltage profile 150 corresponds to electrochemical cell assembly 108 operating in a rest operating state for at least a predetermined minimum threshold time duration, to help ensure that open circuit voltage values of extracted voltage profile 150 reflect electrochemical cell assembly 108 being at least substantially relaxed. For example, referring again to FIG. 9, duration the of rest operating state 904 is short compared to respective durations ta and t_{f} of rest operating state 902 and rest operating state 906. As such, some embodiments of extracted profile module 136 may exclude an open circuit voltage value corresponding to rest operating state 904 from extracted voltage profile 150 due to the relatively short duration of rest operating state 904. Additionally, certain embodiments of other functions 128 control operation of electrochemical cell assembly 108 to cause rest operating states of electrochemical cell assembly 108 to have predetermined time durations, to help ensure that rest operation state durations are sufficiently long to enable voltage V_{cell} settle to open circuit values during rest operating states.

Referring again to FIGS. 1 and 7, in certain embodiments of block 708, extracted profile module 136 generates extracted voltage profile 150 such that all open circuit voltage values included in extracted voltage profile 150 have a common over-potential polarity. For example, extracted profile module 136 may generate extracted voltage profile 150 such that all open circuit voltage values included in extracted voltage profile 150 have a positive over-potential polarity, thereby causing all open circuit voltage values to correspond to respective rest operating states during one or more charging intervals of electrochemical cell assembly 108. As another example, extracted profile module 136 may generate extracted voltage profile 150 such that all open circuit voltage values included in extracted voltage profile 150 have a negative over-potential polarity, thereby causing all open circuit voltage values to correspond to respective rest operating states during one or more discharging intervals of electrochemical cell assembly 108.

Alternately or additionally, extracted profile module 136 may be configured to consider one or more additional characteristics of data of raw voltage profile 148 when determining whether to include the data in extracted voltage profile 150. For example, certain embodiments of extracted profile module 136 are configured to exclude one or more portions of raw voltage profile 148 where over-potential has not reached a steady-state value during charging, e.g., where over-potential is being built up after beginning charging or resuming charging. As another example, some embodiments of extracted profile module 136 are configured to exclude one or more portions of raw voltage profile 148 where over-potential has not reached a steady-state value during discharging, e.g., where over-potential is being built up after beginning discharging or resuming discharging. Additionally, some embodiments of extracted profile module 136 as configured to exclude portions of raw voltage profile 148 where magnitude of over-potential of electrochemical cell assembly 108 is less than a predetermined threshold value. Furthermore, particular embodiments of extracted profile module 136 are configured to exclude from extracted voltage profile 150 a lowest open circuit voltage value, and/or a highest open circuit voltage value, included in raw voltage profile 148.

Referring again to FIG. 7, method 700 proceeds from block 708 to a block 710 where cost function module 140 varies parameters of model 154 of electrochemical cell assembly 108 until one or more cost functions 156 meet respective predetermined conditions. Specifically, cost function module 140 evaluates each cost function 156 using different parameter values until a value of the cost function 156 is less than or equal to a respective maximum permissible value of the cost function. Each cost function 156 represents error in model 154 with respect to data associated with extracted voltage profile 150, or stated differently, each cost function 156 represents mismatch between model 154 and data of extracted voltage profile 150. Accordingly, each cost function 156 represents inaccuracy in model 154. While not required, it is anticipated that at least two of the cost functions 156 represent error in model 154 in different respective manners. Accordingly, executing block 710 helps minimize error in model 154 by finding a set of parameters of model 154 that cause model 154 to closely represent extracted voltage profile 150. In certain embodiments, cost function module 140 varies the following parameters of model 154 in block 708: (i) LAM_{NE} in electrochemical cell assembly 108, (ii) LAM_{PE} in electrochemical cell assembly 108, (iii) LLI in electrochemical cell assembly 108, and (iv) model capacity offset (MCO), where MCO represents difference between a capacity of electrochemical cell assembly 108 at a starting point of model 154 and a capacity of electrochemical cell assembly 108 at a starting point of extracted voltage profile 150. Cost function module 140 need not vary all parameters in each cost function 156, and cost function module 140 need not vary the same parameters in each cost function 156. In some embodiments, model 154 represents open circuit values of voltage V_{cell} as a function capacity of capacity of electrochemical cell assembly 108, and the parameters of model 154 include LAM_{NE}, LAM_{PE}, LLi, and MCO. In these embodiments, open circuit values of voltage V_{cell} as a function capacity of electrochemical cell assembly 108 expressed by model 154 will vary according to the respective values of parameters LAM_{NE}, LAM_{PE}, LLi, and MCO of model 154. Model 154 may also represent one or more of (i) change in capacity of electrochemical cell assembly 108 with respect to change in V_{cell}, as a function of capacity of electrochemical cell assembly 108 and (ii) change in V_{cell} with respect to change in capacity of electrochemical cell assembly 108, as a function of capacity of electrochemical cell assembly 108.

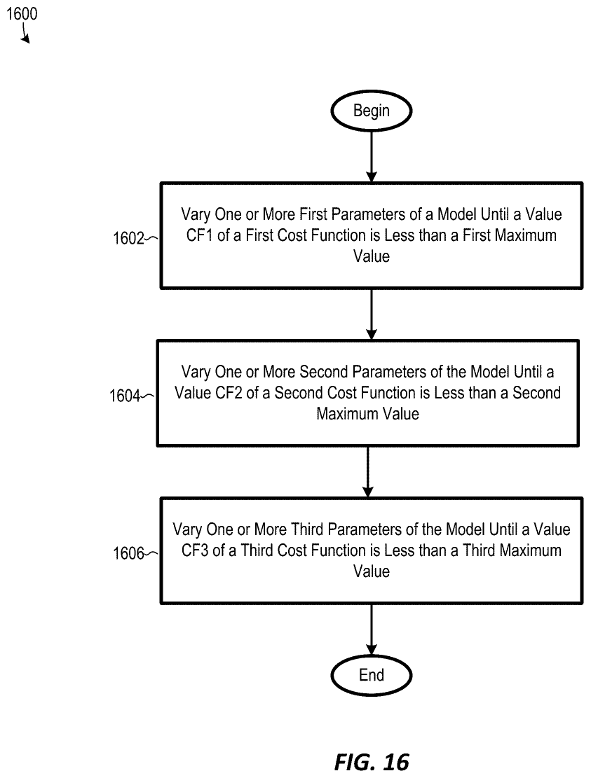

Certain embodiments of cost function module 140 evaluate multiple cost functions 156 by (i) evaluating only one cost function 156 at a time, i.e., by varying parameters of only one cost function 156 at a time until the cost function 156 meets a respective predetermined condition, and (ii) using the final parameters of a given cost function 156 as starting parameters for a subsequently evaluated cost function 156 (if any). For example, FIG. 16 is a flow chart of method 1600 for evaluating cost functions 156, where method 1600 is one example of block 710 in an embodiment where cost function module 140 sequentially evaluates three cost functions 156. It is understood, though, that cost function module 140 may evaluate a different quantity of cost functions 156 in block 710. For example, cost function module 140 may evaluate only one or two cost functions 156 in block 710, or cost function module 140 may evaluate four or more cost functions 156 in block 710.

In a block 1602 of method 1600, cost function module 140 varies one or more first parameters, e.g., LAM_{NE}, LAM_{PE}, LLI, and/or MCO, of model 154 until a value CF1 of a first cost function is less than or equal to a first maximum permissible value. Value CF1 of the first cost function 156 represents error in model 154 in a first manner, and varying parameters of model 154 until value CF1 is less than the first maximum permissible value therefore helps minimize error in model 154.

Method 1600 proceeds from block 1602 to a block 1604 where cost function module 140 varies one or more second parameters, e.g., LAM_{NE}, LAM_{PE}, LLI, and/or MCO, of model 154 until a value CF2 of a second cost function 156 is less than or equal to a second maximum permissible value. The second parameters of block 1604 may be partially or completely different from the first parameters of block 1602. Value CF2 of the second cost function 156 represents error in model 154 in a second manner, and varying parameters of model 154 until value CF2 is less than the second maximum permissible value therefore further helps minimize error in model 154. Importantly, all parameters of model 154 at the beginning of execution of block 1604 are the same as all parameters of model 154 at the end of block 1602, such that optimization of model 154 in block 1604 picks up where optimization of model 154 concluded in block 1602, thereby helping minimize time and processing resources needed to execute block 1604.

Method 1600 proceeds from block 1604 to a block 1606 where cost function module 140 varies one or more third parameters, e.g., LAM_{NE}, LAM_{PE}, LLI, and/or MCO, of model 154 until a value CF3 of a third cost function 156 is less than or equal to a third maximum permissible value. The third parameters of block 1604 may be partially or completely different from the second parameters of block 1604. Value CF3 of the third cost function 156 represents error in model 154 in a third manner, and varying parameters of model 154 until value CF3 is less than the third maximum permissible value therefore further helps minimize error in model 154. Importantly, all parameters of model 154 at the beginning of execution of block 1606 are the same as all parameters of model 154 at the end of block 1604, such that optimization of model 154 in block 1606 picks up where optimization of model 154 concluded in block 1604, thereby helping minimize time and processing resources needed to execute block 1604.

Discussed below are several examples of possible cost functions 156 that cost function module 140 may evaluate in block 710. In certain embodiments, cost function module 140 evaluates two or more of the following exemplary cost functions 156 at different times, such as in a manner similar to that illustrated in FIG. 16. It is understood, though, that cost function module 140 is not limited to evaluating the following exemplary cost functions 156.

### Example Cost Function 1

In certain embodiments, cost function module 140 evaluates a cost function referred to as MSE(OCV), which represents the mean of squared differences between (i) open circuit voltage values expressed by model 154 at respective capacities of electrochemical cell assembly 108 corresponding to the open circuit voltage values of electrochemical cell assembly 108 included in extracted voltage profile 150 and (ii) the plurality of the open circuit voltage values of electrochemical cell assembly 108 included in extracted voltage profile 150, at different model 154 parameter values until a value of MSE(OCV) is less than or equal to a maximum permissible value. For example, assume that extracted voltage profile 150 is extracted voltage profile 1300 of FIG. 13. In this example, cost function module 140 evaluates, at different parameters of model 154, the following example MSE(OCV) function until a value of the function is less than or equal to a maximum permissible value: an average of (i) the square of the difference between open circuit value V₂₄ of extracted voltage profile 1300 at capacity Q₂₄ and an open circuit voltage value of model 154 at capacity Q₂₄, (ii) the square of the difference between open circuit value V₂ of extracted voltage profile 1300 at capacity Q₂ and an open circuit voltage value of model 154 at capacity Q₂, (iii) the square of the difference between open circuit value V₅ of extracted voltage profile 1300 at capacity Q₅ and an open circuit voltage value of model 154 at capacity Q₅, and (iv) the square of the difference between open circuit value V₇ of extracted voltage profile 1300 at capacity Q₇ and an open circuit voltage value of model 154 at capacity Q₇.

### Example Cost Function 2

In certain embodiments, cost function module 140 evaluates a cost function referred to as MSE(dVdQ(OCV)), which represents mean of squared differences between (i) slope of an open circuit voltage versus capacity curve, as expressed by model 154, at each of the plurality of open circuit voltage values of electrochemical cell assembly 108 included in extracted voltage profile 150, and (ii) slope of extracted voltage profile 150 at each of the plurality of open circuit voltage values of electrochemical cell assembly 108 included in extracted voltage profile 150, at different model 154 parameter values until a value of MSE(dVdQ(OCV)) is less than or equal to a maximum permissible value. For example, assume again that extracted voltage profile 150 is extracted voltage profile 1300 of FIG. 13. In this example, cost function module 140 evaluates, at different parameters of model 154, the following example MSE(dVdQ(OCV)) function until a value of the function is less than or equal to a maximum permissible value: an average of (i) the square of a difference between slope of extracted voltage profile 1300 at capacity Q₂₄ and slope of an open circuit voltage versus capacity curve of model 154 at capacity Q₂₄, (ii) the square of a difference between slope of extracted voltage profile 1300 at capacity Q₂ and slope of the open circuit voltage versus capacity curve of model 154 at capacity Q₂, (iii) the square of a difference between slope of extracted voltage profile 1300 at capacity Q₅ and slope of the open circuit voltage versus capacity curve of model 154 at capacity Q₅, and (iv) the square of a difference between slope of extracted voltage profile 1300 at capacity Q₇ and slope of the open circuit voltage versus capacity curve of model 154 at capacity Q₇.

### Example Cost Function 3

In certain embodiments, cost function module 140 evaluates a cost function referred to as MSE(dQdV(OCV)), which represents mean of squared differences between (i) slope of a capacity versus open circuit voltage curve, as expressed by model 154, at each of the plurality of open circuit voltage values of electrochemical cell assembly 108 included in extracted voltage profile 150, and (ii) slope of a capacity versus voltage curve of electrochemical cell assembly 108 based on an inverse of extracted voltage profile 150, at each of the plurality of open circuit voltage values of electrochemical cell assembly 108 included in extracted voltage profile 150, at different model 154 parameter values until a value of MSE(dQdV(OCV)) is less than or equal to a maximum permissible value. For example, assume again that extracted voltage profile 150 is extracted voltage profile 1300 of FIG. 13. In this example, cost function module 140 evaluates, at different parameters of model 154, the following example MSE(dQdV(OCV)) function until a value of the function is less than or equal to a maximum permissible value: average of (i) the square of a difference between slope of an inverse of extracted voltage profile 1300 at voltage V₂₄ and slope of the capacity versus open circuit voltage curve of model 154 at voltage V₂₄, (ii) the square of a difference between slope of an inverse of extracted voltage profile 1300 at voltage V₂ and slope of the capacity versus open circuit voltage curve of model 154 at voltage V₂, (iii) the square of a difference between slope of an inverse of extracted voltage profile 1300 at voltage V₅ and slope of the capacity versus open circuit voltage curve of model 154 at voltage V₅, and (iv) the square of a difference between slope of an inverse of extracted voltage profile 1300 at voltage V₇ and slope of the capacity versus open circuit voltage curve of model 154 at voltage V₇.

### Example Cost Function 4

In certain embodiments, cost function module 140 evaluates a cost function referred to as MSE (Q), which represents mean of squared differences between (i) capacity of the electrochemical cell assembly, as expressed by the model of the electrochemical cell assembly, at each of the plurality of open circuit voltage values of electrochemical cell assembly 108 included in extracted voltage profile 150, and (ii) capacity of electrochemical cell assembly 108, as expressed by extracted voltage profile 150, at each of the plurality of open circuit voltage values of electrochemical cell assembly 108 included in extracted voltage profile 150, at different model 154 parameter values until a value of MSE (Q) is less than or equal to a maximum permissible value. For example, assume again that extracted voltage profile 150 is extracted voltage profile 1300 of FIG. 13. In this example, cost function module 140 evaluates, at different parameters of model 154, of the following MSE (Q) function until a value of the function is less than or equal to a maximum permissible value: an average of of (i) the square of a difference between capacity Q₂₄ of extracted voltage profile 1300 at open circuit value V₂₄ and a capacity value of model 154 at open circuit value V₂₄, (ii) the square of a difference between capacity Q₂ of extracted voltage profile 1300 at open circuit value V₂ and a capacity value of model 154 at open circuit value V₂, (iii) the square of a difference between capacity Q₅ of extracted voltage profile 1300 at open circuit value V₅ and a capacity value of model 154 at open circuit value V₅, and (iv) the square of a difference between capacity Q₇ of extracted voltage profile 1300 at open circuit value V₇ and a capacity value of model 154 at open circuit value V₇.

### Example Cost Function 5

In certain embodiments, cost function module 140 evaluates a cost function equal to W₁*MSE(dVdQ(OCV))+W₂*MSE(OCV), where W₁ and W₂ are optional weights or scaling factors, at different parameter values until a value of the cost function is less than or equal to a maximum permissible value. MSE(dVdQ(OCV)) is defined as discussed above with respect to Example Cost Function 2, and MSE(OCV) is defined as discussed above with respect to Example Cost Function 1. Example Cost Function 5 could be modified to be a function of W₁*MSE(dVdQ(OCV)) and W₂*MSE(OCV) other than a sum of these two terms.

Referring again to FIG. 7, method 700 proceeds from block 710 to a block 712 where reporting module 142 determines thermodynamic SOD 158 at least based partially on the parameters of model 154 at the conclusion of block 710. For example, assume that final parameters of model 154 at the conclusion of block 710 are LAM_{NE}_F, LAM_{PE}_F, LLI_F, and MCO_F. In this example, reporting module 142 may set thermodynamic SOD 158 equal to a vector SOD_therm as follows, which expresses each of LAM_{NE}, LAM_{PE}, and LLI, of electrochemical cell assembly 108: SOD_therm=[LAM_{NE}_F, LAM_{PE}_F, and LLI_F].

Referring again to FIG. 1, accuracy of model 154 may potentially be increased by evaluating one or more cost functions to minimize a difference between a differential profile 152 of electrochemical cell assembly 108 and a corresponding differential profile expressed by model 154, with the potential downside of interfering with normal operation of electrochemical cell assembly 108 due to the possible need to slowly charge and/or discharge electrochemical cell assembly 108 to obtain the requisite data. Accordingly, certain embodiments of thermodynamic SOD determination system 106 including optional differential profile module 138 are further configured to evaluate one or more cost functions to minimize a difference between a differential profile 152 of electrochemical cell assembly 108 generated from measured data, e.g., from sensed voltage data 144, from sensed charge data 146, and/or from extracted voltage profile 150, and a corresponding differential profile expressed by model 154.

For example, FIG. 17 is a flow chart of a method 1700 for in-situ determination of a thermodynamic state of degradation of an electrochemical cell assembly, and method 1700 is another example of a method performed by thermodynamic SOD determination system 106. However, method 1700 could be adapted for execution by a SOD determination system other than thermodynamic SOD determination system 106.

In a block 1702 of method 1700, voltage sensing module 130 senses voltage V_{cell} of electrochemical cell assembly 108 in-situ, i.e., when it is deployed in its intended application, over one or more operating intervals of electrochemical cell assembly 108 to generate sensed voltage data 144, in a manner similar to that discussed above with respect to block 702 of FIG. 7. However, block 1702 potentially differs from block 702 in that at least some of sensed voltage data 144 includes values of voltage V_{cell} sensed during low magnitude, e.g., C/20 or C/50, constant current (or constant power) charging or discharging of electrochemical cell assembly 108, such as to facilitate determination of one or more differential profiles in block 1710 (discussed below).

Blocks 1704 and 1706 of method 1700 are similar to blocks 704 and 706 of method 700, respectively. In particular, method 1700 proceeds from block 1702 to block 1704 where charge sensing module 132 determines charge flowing between electrochemical cell assembly 108 and external circuitry over the same one or more operating interval of electrochemical cell assembly 108 as block 1702, to generate sensed charge data 146, in a manner similar to that discussed above with respect to block 704 of method 700. Method 1700 proceeds from block 704 to block 1706 where raw voltage profile module 134 constructs raw voltage profile 148 from each of sensed voltage data 144 and sensed charge data 146, in a manner similar to that discussed above with respect to block 706 of method 700.

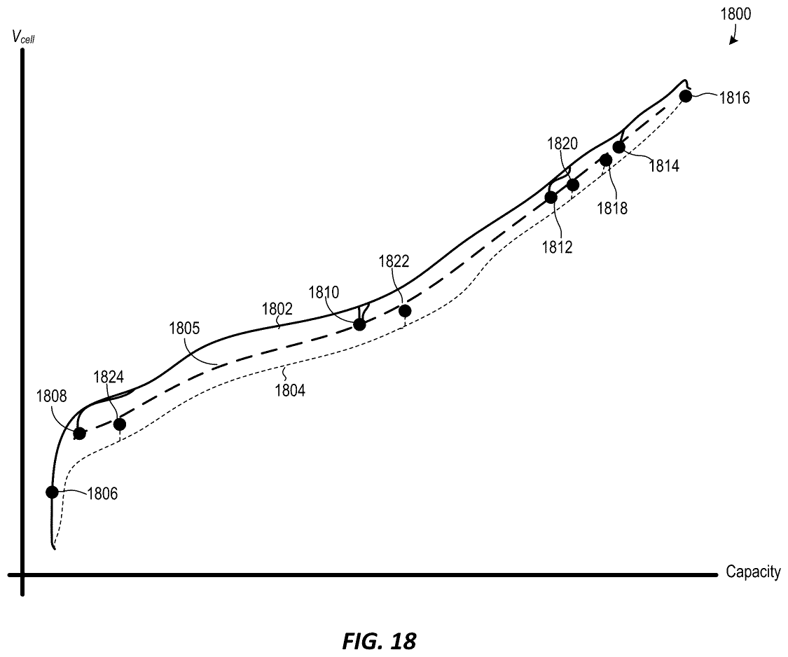

Method 1700 proceeds from block 1706 to block 1708 where extracted profile module 136 extracts a subset of raw voltage profile 148 constructed in block 1706 to obtain extracted voltage profile 150. Extracted profile module 136 performs block 1708 in a manner similar to that discussed above with respect to block 708 of FIG. 7, although in some embodiments, extracted voltage profile 150 includes an average of (i) voltage V_{cell} during charging of electrochemical cell assembly 108 and (ii) voltage V_{cell} during discharging of electrochemical cell assembly 108, as a function of capacity of the electrochemical cell assembly, such as for use when determining one or more differential profiles in block 1710 (discussed below). For example, FIG. 18 is a graph 1800 of voltage V_{cell} versus capacity illustrating an example of extracted voltage profile 150 including an average of voltage V_{cell} during charging of electrochemical cell assembly 108 and discharging of electrochemical cell assembly 108. FIG. 18 includes a curve 1802 of voltage V_{cell} versus capacity during charging of electrochemical cell assembly 108, a curve 1804 of voltage V_{cell} versus capacity during discharging of electrochemical cell assembly 108, and curve 1805 which is an average of curve 1802 and curve 1804. FIG. 18 further includes (i) circles indicating open circuit voltage values 1808, 1810, 1812, 1814, and 1816 of voltage V_{cell} during charging of electrochemical cell assembly 108 and (ii) circles indicating open circuit voltage values 1818, 1820, 1822, 1824, and 1806 of voltage V_{cell} during discharging of electrochemical cell assembly 108. Curve 1805 is an example of extracted voltage profile 150 in embodiments where extracted voltage profile 150 represents of average value of voltage V_{cell} during charging and discharging of electrochemical cell assembly 108. Data represented by curves curve 1802 and curve 1804 is, for example, part of raw voltage profile 148. While FIG. 18 illustrates curve 1805 coinciding with some of the open circuit voltage values in graph 1800, it should be noted that the average of voltage V_{cell} during charging and discharging of electrochemical cell assembly 108 need not coincide with open circuit voltage values. For example, open circuit voltage values will typically exhibit hysteresis which may cause the open circuit voltage values to differ from average values of voltage V_{cell}.

Referring again to FIG. 17, method 1700 proceeds from block 1708 to a block 1710 where differential profile module 138 generates one or more differential profiles 152. One or more differential profiles 152 include at least one of (i) a differential charge profile representing change in capacity of electrochemical cell assembly 108 with respect to change in voltage V_{cell} of electrochemical cell assembly 108, as a function of capacity of electrochemical cell assembly 108, and (ii) a differential voltage profile representing change in voltage V_{cell} of electrochemical cell assembly 108 with respect to change in capacity of electrochemical cell assembly 108, as a function of capacity of electrochemical cell assembly 108. Discussed below are several examples of how differential profile module 138 could generate one or more differential profiles 152. However, differential profile module 138 is not limited to operating according to the following examples.

Certain embodiments of differential profile module 138 are configured to generate one or more differential profiles using data corresponding to open circuit values of voltage V_{cell}. For example, some embodiments of differential profile module 138 are configured to generate a differential charge profile by differentiating each value of capacity of extracted voltage profile 150 with respect to voltage V_{cell} corresponding to the capacity value, at each open circuit value of voltage V_{cell} included in extracted voltage profile 150. As another example, certain embodiments of differential profile module 138 are configured to generate a differential voltage profile by differentiating each value of voltage V_{cell} of extracted voltage profile 1500 with respect to capacity corresponding to the value of voltage V_{cell}, at each open circuit value of voltage V_{cell} included in extracted voltage profile 150.

Additionally, particular embodiments of differential profile module 138 are configure to generate a differential charge profile or a differential voltage profile by fitting a differential charge curve or a differential voltage curve to a curve representing average value of voltage V_{cell} during charging and discharging of electrochemical cell assembly 108, such a curve 1805 of FIG. 18. Furthermore, some embodiments of differential profile module 138 are configured to generate a differential charge profile or a differential voltage profile by fitting a differential charge curve or a differential voltage curve to (i) one or more portions of extracted voltage profile 150 corresponding to charging of electrochemical cell assembly 108 and/or (ii) one or more portions of extracted voltage profile 150 corresponding to discharging of electrochemical cell assembly 108.

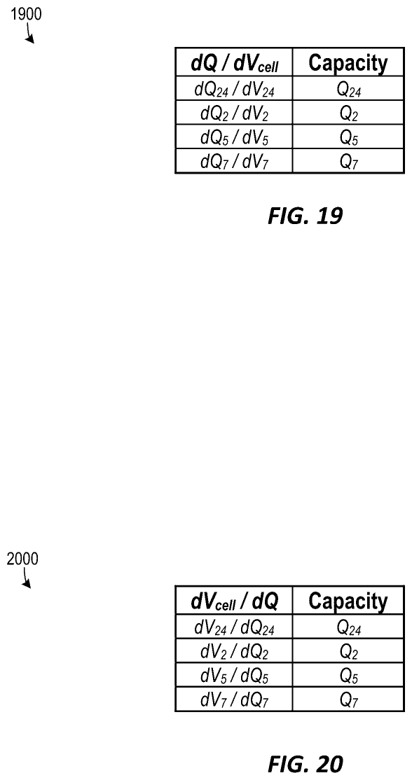

FIG. 19 is a table illustrating a differential charge profile 1900, which is one example of a differential profile 152 generated by differential profile module 138 using open circuit voltage data. Differential charge profile 1900 is based on the data of extracted voltage profile 1300 of FIG. 13, and differential charge profile 1900 represents change in capacity of electrochemical cell assembly 108 with respect to change in voltage V_{cell} of electrochemical cell assembly 108, as a function of capacity of electrochemical cell assembly 108 at each open circuit value of voltage V_{cell} in extracted voltage profile 1300. Differential profile module 138 generates differential charge profile 1900, for example, by differentiating each value of capacity of extracted voltage profile 1300 with respect to voltage V_{cell} corresponding to the capacity value at each open circuit value of voltage V_{cell} in extracted voltage profile 1300.

FIG. 20 is a table illustrating a differential voltage profile 2000, which is another example of a differential profile 152 generated by differential profile module 138 using open circuit voltage data. Differential voltage profile 2000 is based on the data of extracted voltage profile 1300 of FIG. 13, and differential voltage profile 2000 represents change in voltage V_{cell} of electrochemical cell assembly 108 with respect to change in capacity of electrochemical cell assembly 108, as a function of capacity of electrochemical cell assembly 108 at each open circuit value of voltage V_{cell} in extracted voltage profile 1300. Differential profile module 138 generates differential voltage profile 2000, for example, by differentiating each value of voltage V_{cell} of extracted voltage profile 1300 with respect to capacity corresponding to the value of voltage V_{cell} at each open circuit value of voltage V_{cell} in extracted voltage profile 1300.

Referring again to FIG. 17, method 1700 proceeds from block 1710 to a block 1712 where cost function module 140 varies parameters of model 154 of electrochemical cell assembly 108 until at least two cost functions 156 meet respective predetermined conditions. Cost function module 140 performs block 1712 in a manner similar to how cost function module 140 performs block 710 of method 700. For example, cost function module 140 may evaluate two or more cost functions in block 1712 in a manner similar to that discussed above with respect to method 1600 of FIG. 16. However, in contrast with block 710 of method 700, at least one of the cost functions evaluated in block 1712 is based on one or more differential profiles 152, such as a differential charge profile or a differential voltage profile.

Discussed below are two examples of possible cost functions 156 that cost function module 140 may evaluate in block 1712. In certain embodiments, cost function module 140 evaluates the cost functions 156 at different times, such as in a manner similar to that illustrated in FIG. 16. It is understood, though, that cost function module 140 is not limited to evaluating the following exemplary cost functions 156. Additionally, it should be noted that cost function module 140 may evaluate one or more of the cost functions discussed above with respect to FIG. 7.

### Example Cost Function 6

In certain embodiments, cost function module 140 evaluates a cost function referred to as MSE(dQdV), which represents the mean of squared differences between (i) a differential charge profile expressed by model 154 and (ii) a differential charge profile generated from extracted voltage profile 150, at different model 154 parameter values until a value of MSE(dQdV) is less than or equal to a maximum permissible value. For example, in some embodiments, cost function module 140 evaluates, at different parameters of model 154, the following MSE(dQdV) function of EQN. 1 below until a value of the function is less than or equal to a maximum permissible value, where

$$\frac{{dQ}_{m 154}}{{d V}_{m 154}} ( i )$$

is the instantaneous slope of model 154's capacity with respect to potential at charge interval i

$$\frac{{dQ}_{e 150}}{{d V}_{e 150}} ( i )$$

is the instantaneous slope of extracted voltage profile 150's capacity with respect to potential at charge interval i, and n is the quantity of values in the differential charge profile.

$$MSE = \frac{{\sum }_{i = 0}^{i = n} {( \frac{{dQ}_{m 154}}{{d V}_{m 154}} ( i ) - \frac{{dQ}_{e 150}}{{d V}_{e 150}} ( i ) )}^{2}}{n} \qquad ( EQN . 1 )$$

### Example Cost Function 7

In certain embodiments, cost function module 140 evaluates a cost function equal to W₃*MSE(dQdV)+W₄*MSE(OCV) at different parameter values until a value of the sum of the cost function is less than or equal to a maximum permissible value. MSE(dQdV) is defined as discussed above with respect to Example Cost Function 6, MSE(OCV) is defined as discussed above with respect to Example Cost Function 1, and W₃ and W₄ are optional weights or scaling factors. Example Cost Function 7 could be modified to be a function of W₃*MSE(dQdV) and W₄*MSE(OCV) other than a sum of these two terms.

Referring again to FIG. 17, method 1700 proceeds from block 1712 to a block 1714 where reporting module 142 determines thermodynamic SOD 158 at least based partially on the parameters of model 154 at the conclusion of block 1712. For example, assume that final parameters of model 154 at the conclusion of block 1712 are LAM_{NE}_F2, LAM_{PE}_F2, LLI_F2, and MCO_F2. In this example, reporting module 142 may set thermodynamic SOD 158 equal to a vector SOD_therm2 as follows, which expresses each of LAM_{NE}, LAM_{PE}, and LLI, of electrochemical cell assembly 108: SOD_therm2=[LAM_{NE}_F2, LAM_{PE}_F2, and LLI_F2].

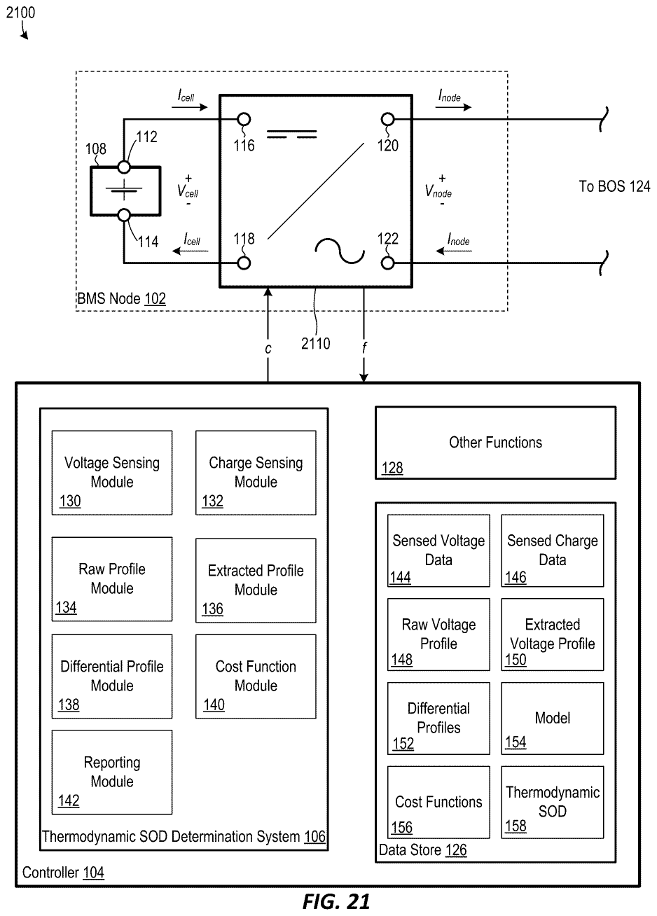

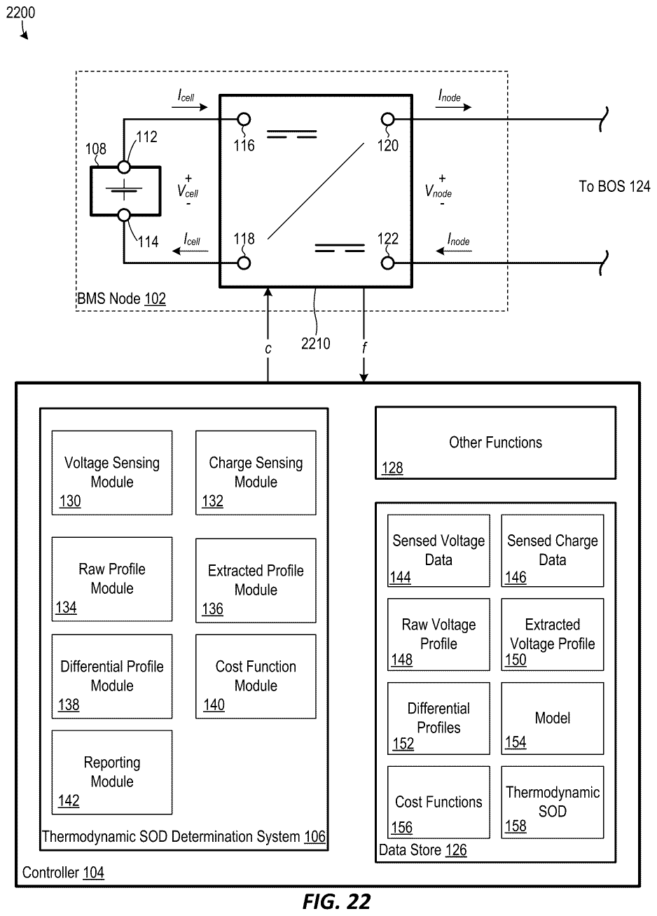

Referring again to FIG. 1, as discussed above, in some embodiments, power converter 110 may be an inverter or a DC-to-DC converter. For example, FIG. 21 is a schematic diagram of an electrical environment 2100, which is an embodiment of electrical environment 100 (FIG. 1) where power converter 110 is embodied by an inverter 2110. As another example, FIG. 22 is a schematic diagram of an electrical environment 2200, which is an embodiment of electrical environment 100 where power converter 110 is embodied by a DC-to-DC converter 2210.

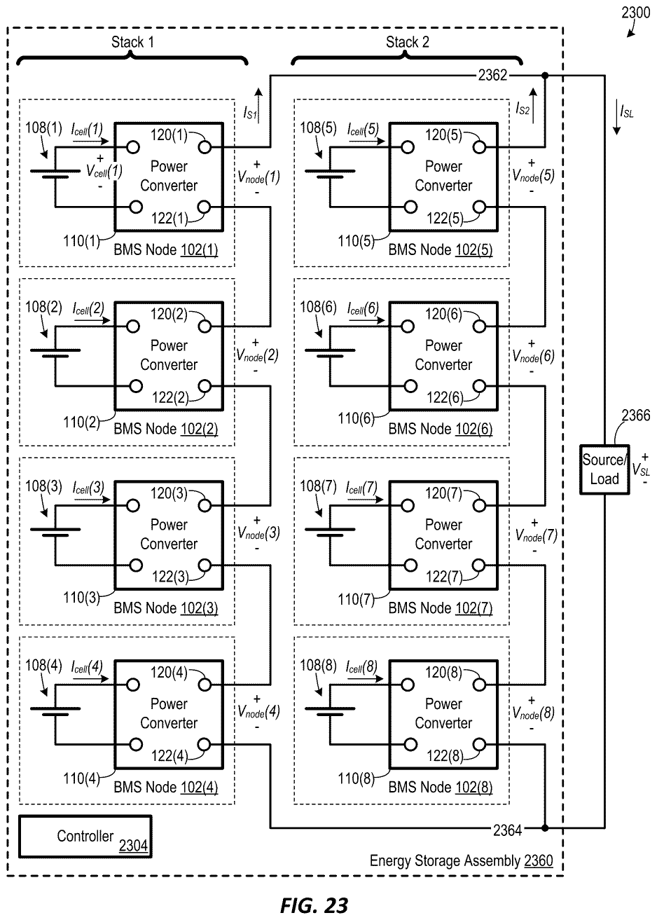

Referring again to FIG. 1, controller 104 is optionally configured to control one or more BMS nodes (not shown) in addition to BMS node 102. For example, FIG. 23 is a schematic diagram of an electrical environment 2300 including an energy storage assembly 2360 and a source/load 2366. Energy storage assembly 2360 includes a plurality of BMS nodes 102 and a controller 2304. Some elements of BMS nodes 102 are not labeled in FIG. 23 for illustrative clarity. BMS nodes 102 are arranged into two stacks, i.e., a Stack 1 and a Stack 2, in energy storage assembly 2360. Stack 1 includes BMS nodes 102(1)-102(4), and Stack 2 includes BMS nodes 102(5)-102(8). The quantity of BMS nodes 102 in each stack may vary, and each stack need not include the same quantity of BMS nodes 102. Additionally, the quantity of stacks in energy storage assembly 2360 may vary. For example, in one alternate embodiment, energy storage assembly 2360 includes solely Stack 1, i.e., Stack 2 is omitted. As another example, in another alternate embodiment, energy storage assembly 2360 includes one or more stacks in addition to Stack 1 and Stack 2.

BMS nodes 102 within a given stack are electrically coupled in series via output ports 120 and 122 between a first power bus 2362 and a second power bus 2364. For example, BMS node 102(1) is electrically coupled in series with first power bus 2362 via output port 120(1), and BMS node 102(1) is electrically coupled in series with BMS node 102(2) via output port 122(1). As another example, BMS node 102(2) is electrically coupled in series with BMS node 102(1) via output port 120(2), and BMS node 102(2) is electrically coupled in series with BMS node 102(3) via output port 122(2). Voltages V_{node} across output ports 120 and 122 of BMS nodes 102 may vary among BMS nodes 102. However, current through output ports 120 and 122 is the same for all BMS nodes 102 within a given stack. In particular, a current Iₛ₁ flows through all output ports 120 and 122 in Stack 1, and a current Iₛ₂ flows through all output ports 120 and 122 in Stack 2.

Stack 1 and Stack 2 are electrically coupled in parallel with source/load 2366 via first power bus 2362 and second power bus 2364. Stack 1 and Stack 2 collectively provide a current I_{SL} and a voltage V_{SL} to source/load 2366. Source/load 2366 provides electric power to energy storage assembly 2360 when source/load 2366 operates as an electric power source, and source/load 2366 consumes electric power from energy storage assembly 2360 when source/load 2366 operates as a load. Although source/load 2366 is symbolically shown as a single element, source/load 2366 could include a plurality of elements, such as a source and a load, a plurality of sources, and/or a plurality of loads. Additionally, source/load 2366 may include interface devices, such as DC-to-AC converters, DC-to-DC converters, and/or transformers, configured to electrically couple energy storage assembly 2360 with an energy source and/or an energy sink. In some embodiments, source/load 2366 includes one or more of an alternating current (AC) electric power system (e.g., an AC electric power grid), a DC electric power system, an electromechanical device, and a photovoltaic device, which are optionally electrically coupled to energy storage assembly 2360 via a DC-to-AC converter of source/load 2366, a DC-to-DC converter of source/load 2366, and/or a transformer of source/load 2366. However, source/load 2366 can take other forms without departing from the scope hereof.

Controller 2304 is an embodiment of controller 104 (FIG. 1) which is configured to determine a respective SOD for each electrochemical cell assembly 108 of energy storage assembly 2360, such by executing method 700 (FIG. 7) or method 1700 (FIG. 17) with respect to each electrochemical cell assembly 108. Although controller 2304 is depicted as a single element, controller 2304 may include multiple constituent sub-elements which need not be co-located. Additionally, controller 2304 could be partially or fully combined with one or more other elements. Certain embodiments of controller 2304 are capable of determining SOD of one electrochemical cell assembly 108 at a time, while other embodiments of controller 2304 are configured to simultaneously determine SOD of two or more electrochemical cell assemblies 108, such as by executing two or more instances of method 700, or method 1700, in parallel. Some embodiments of controller 2304 are configured to determine SOD of electrochemical cell assemblies 108 of energy storage assembly 2360 according to a predetermined schedule, e.g., periodically, and certain embodiments of controller 2304 are configured to determine SOD of one or more electrochemical cell assemblies 108 on demand.

Furthermore, particular embodiment of controller 2304 are configured to control BMS nodes 102 to execute a global operating strategy of energy storage assembly 2360. A global operating strategy of energy storage assembly 2360 is an operating strategy for all of energy storage assembly 2360. A global operating strategy may be static or dynamic. Examples of global operating strategies for energy storage assembly 2360 include, but are not limited to, (1) providing substantially constant power to source/load 2366, (2) providing substantially constant current I_{SL} to source/load 2366, (3) providing substantially constant voltage V_{SL} to source/load 2366, (4) receiving substantially constant power from source/load 2366, (5) receiving substantially constant voltage V_{SL} from source/load 2366, (6) receiving substantially constant current I_{SL} from source/load 2366, (7) operating energy storage assembly 2360 in a standby mode where energy storage assembly 2360 neither provides power to source/load 2366 nor receives power from source/load 2366, (8) maintaining a constant overall state of charge of Stack 1 and Stack 2, (9) maintaining a constant overall rate of charge, or rate of discharge, of Stack 1 and Stack 2, (10) maintaining Stack 1 and Stack 2 at a common state of charge as the stacks charge or discharge, (11) stabilizing output power of an external power generation system, such as a photovoltaic power generation system, by absorbing excess power from the power generation system or by providing power to compensate for a shortage in power produced by the power generation system, and (12) stabilizing frequency and/or voltage of an AC power grid by absorbing power from the AC power grid or providing power to the AC power grid. It should be noted that a global operating strategy may include more than one component. For example, a global operating strategy may include maintaining a substantially constant state of charge among Stack 1 and Stack 2 while providing a constant power to source/load 2366 or while receiving a constant power from source/load 2366. As another example, a global operating strategy may include maintaining a substantially constant state of charge among Stack 1 and Stack 2 while providing a constant current I_{SL} to source/load 2366. Particular embodiments of controller 2304 are configured to determine SOD of one or more electrochemical cell assemblies 108, such as by executing method 700 or 1700, while maintaining a global operating strategy of energy storage assembly 2360.

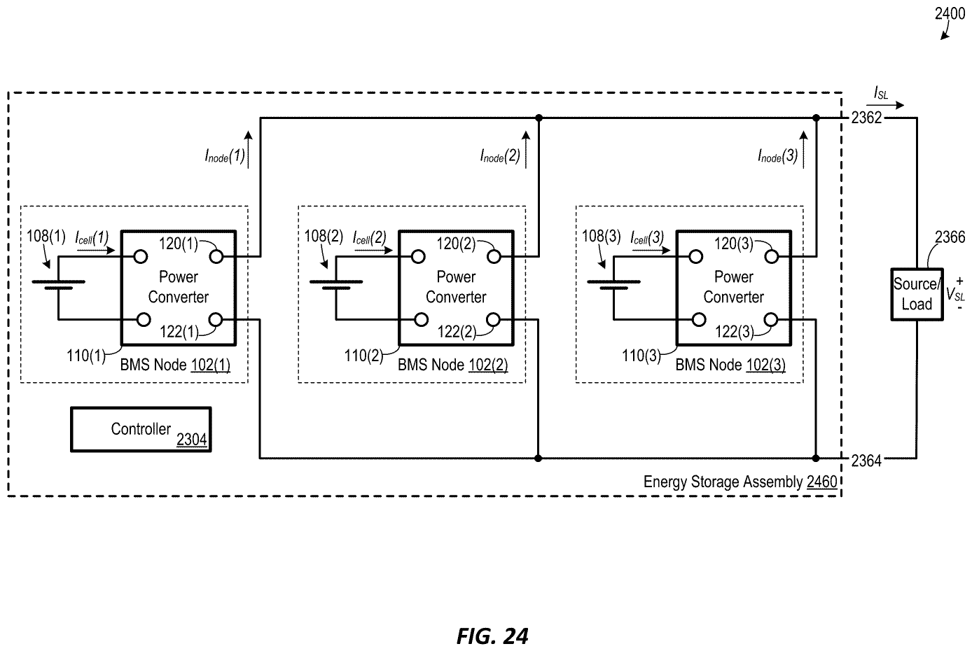

FIG. 24 is a schematic diagram of an electrical environment 2400, which is an alternate embodiment of electrical environment 2300 (FIG. 23) where energy storage assembly 2360 is replaced with an energy storage assembly 2460. Energy storage assembly 2460 differs from energy storage assembly 2360 in that energy storage assembly 2460 includes a plurality of BMS nodes 102 electrically coupled in parallel via first power bus 2362 and second power bus 2364, instead of stacks of BMS nodes 102 electrically coupled in series. BMS nodes 102 will have a common voltage V_{SL} across their output ports 120 and 122. However, each BMS node 102 will have a respective current I_{node} flowing through its output ports 120 and 122, where currents I_{node} sum to current I_{SL} flowing through source/load 2366. Energy storage assembly 2460 operates in a manner similar to energy storage assembly 2360. For example, controller 2304 is configured to determine SOD of each electrochemical cell assembly 108, such as by executing method 700 or 1700 with respect to each electrochemical cell assembly 108. As another example, certain embodiments of controller 2304 are configured to determine SOD of one or more electrochemical cell assemblies 108, such as by executing method 700 or 1700, while maintaining a global operating strategy of energy storage assembly 2460.

Referring again to FIG. 1, example applications of electrochemical cell assembly 108 include, but are not limited to, electrical vehicle applications, battery energy storage applications, and consumer electronic device applications. For example, FIG. 25 is an illustration of an electric vehicle 2500 including an instance of BMS node 102 installed therein and an instance of controller 104 installed therein. Details of BMS node 102 and controller 104 are not shown in FIG. 25 for illustrative clarity. While not required, it is anticipated that electric vehicle 2500 will typically include multiple BMS nodes, such as multiple instances of BMS node 102, where each BMS node may be controlled by a respective controller, or all BMS nodes may be controlled by a common controller analogous to controller 2304 of FIGS. 23 and 24. In embodiments of electric vehicle 2500 where thermodynamic SOD determination system 106 is configured to execute either method 700 or 1700, the one or more operating intervals of block 702 or block 1702 may include (i) one or more time periods where electrochemical cell assembly 108 either is powering electric vehicle 2500 or is being charged and (ii) a plurality of time periods where electrochemical cell assembly 108 is at rest.

As another example, FIG. 26 is a schematic diagram of an electrical environment 2600 including a battery energy storage system (BES) 2602 connected to an electric power grid 2604. Electric power grid 2604 is, for example, an AC electric power grid or a DC electric power grid. Battery energy storage system 2602 includes an instance of BMS node 102 installed therein and an instance of controller 104 installed therein. While not required, it is anticipated that battery energy storage system 2602 will typically include multiple BMS nodes, such as multiple instances of BMS node 102, where each BMS node may be controlled by a respective controller, or all BMS nodes may be controlled by a common controller analogous to controller 2304 of FIGS. 23 and 24. In embodiments of battery energy storage system 2602 where thermodynamic SOD determination system 106 is configured to execute either method 700 or 1700, the one or more operating intervals of block 702 or 1702 may include (i) one or more time periods where electrochemical cell assembly 108 either is powering a load or is being charged and (ii) a plurality of time periods where electrochemical cell assembly 108 is at rest.

As a further example, FIG. 27 is an illustration of a consumer electronic device 2700 including an instance of BMS node 102 installed therein and an instance of controller 104 installed therein. Details of BMS node 102 and controller 104 are not shown in FIG. 27 for illustrative clarity. Although consumer electronic device 2700 is illustrated as being a mobile phone, consumer electronic device 2700 could be another type of device, e.g., a computer, an entertainment device, an audio device, a video device, a communication device other than a mobile phone, a security device, a navigation device, a lighting device, a climate control device, etc. While not required, it is anticipated that consumer electronic device 2700 will typically include multiple BMS nodes, such as multiple instances of BMS node 102, where each BMS node may be controlled by a respective controller, or all BMS nodes may be controlled by a common controller analogous to controller 2304 of FIGS. 23 and 24. In embodiments of consumer electronic device 2700 where thermodynamic SOD determination system 106 is configured to execute either method 700 or 1700, the one or more operating intervals of block 702 or block 1702 may include (i) one or more time periods where electrochemical cell assembly 108 either is powering consumer electronic device 2700 or is being charged and (ii) a plurality of time periods where electrochemical cell assembly 108 is at rest.

### Combinations of Features

Features described above may be combined in various ways without departing from the scope hereof. The following examples illustrate some possible combinations.
(A1) A method for in-situ determination of a thermodynamic state of degradation of an electrochemical cell assembly includes (1) sensing voltage of the electrochemical cell assembly in-situ over one or more operating intervals of the electrochemical cell assembly to generate sensed voltage data, (2) determining charge flowing between the electrochemical cell assembly and external circuitry over the one or more operating intervals of the electrochemical cell assembly to generate sensed charge data, (3) constructing a raw voltage profile from each of (i) the sensed voltage data and (ii) the sensed charge data, the raw voltage profile representing voltage of the electrochemical cell assembly as a function of capacity of the electrochemical cell assembly, (4) extracting a subset of the raw voltage profile to obtain an extracted voltage profile, the extracted voltage profile including a plurality of open circuit voltage values of the electrochemical cell assembly, (5) varying parameters of a model of the electrochemical cell assembly until one or more cost functions meet respective predetermined conditions, each cost function representing error in the model of the electrochemical cell assembly with respect to data associated with the extracted voltage profile, and (6) after the one or more cost functions meet their respective predetermined conditions, determining the thermodynamic state of degradation of the electrochemical cell assembly at least partially based on the parameters of the model of the electrochemical cell assembly.
(A2) In the method denoted as (A1), the one or more operating intervals of the electrochemical cell assembly may include a plurality of rest operating states of the electrochemical cell assembly which are at various states of charge.
(A3) In the method denoted as (A1), the electrochemical cell assembly may be installed in an electric vehicle, and the one or more operating intervals of the electrochemical cell assembly may include (i) one or more time periods where the electrochemical cell assembly either is powering the electric vehicle or is being charged and (ii) a plurality of time periods where the electrochemical cell assembly is at rest.
(A4) In the method denoted as (A1), the electrochemical cell assembly may be installed in a battery energy storage system connected to an electric power grid, and the one or more operating intervals of the electrochemical cell assembly may include (i) one or more time periods where the electrochemical cell assembly either is powering a load or is being charged and (ii) a plurality of time periods where the electrochemical cell assembly is at rest.
(A5) In the methods denoted as (A1), the electrochemical cell assembly may be installed in a consumer electronic device, and the one or more operating intervals of the electrochemical cell assembly may include (ii) one or more time periods where the electrochemical cell assembly either is powering the consumer electronic device or is being charged and (ii) one or more time periods where the electrochemical cell assembly is at rest.
(A6) In the method denoted as (A1), (1) the one or more operating intervals of the electrochemical cell assembly may include a first charging interval of the electrochemical cell assembly and a second charging interval of the electrochemical cell assembly, (2) the first charging interval and the second charging interval may collectively include plurality of time periods where the electrochemical cell assembly is at rest, and (3) at least three time periods of the plurality of time periods where the electrochemical cell assembly is at rest may correspond to different respective capacities of the electrochemical cell assembly.
(A7) In the method denoted as (A1), (1) the plurality of open circuit voltage values of the electrochemical cell assembly included in the extracted voltage profile may correspond to different respective time periods where the electrochemical cell assembly is at rest, and (2) the method may further include tracking, for each of the time periods where the electrochemical cell assembly is at rest, whether the electrochemical cell assembly was operating in a charging operating mode or in a discharging operating mode immediately before the time period where the electrochemical cell assembly is at rest.
(A8) Any one of the methods denoted as (A1) through (A7) may further include selecting the plurality of open circuit voltage values of the electrochemical cell assembly included in the extracted voltage profile such that each open circuit voltage value corresponds to the electrochemical cell assembly operating at rest for at least a predetermined minimum threshold time duration.
(A9) Any one of the methods denoted as (A1) through (A7) may further include selecting the plurality of open circuit voltage values of the electrochemical cell assembly included in the extracted voltage profile such that each open circuit voltage value corresponds to the electrochemical cell assembly operating at rest for a predetermined time duration.
(A10) Any one of the methods denoted as (A1) through (A9) may further include selecting the plurality of open circuit voltage values of the electrochemical cell assembly included in the extracted voltage profile such that each of the open circuit voltage values has a common over-potential polarity.
(A11) In any one of the methods denoted as (A1) through (A10), the parameters of the model of the electrochemical cell assembly may include (i) loss of negative electrode material, (ii) loss of positive electrode material, (iii) loss of lithium inventory, and (iv) model capacity offset.
(A12) In any one of the methods denoted as (A1) through (A11), at least one of the one or more cost functions may include mean of squared differences between (i) open circuit voltage values expressed by the model of the electrochemical cell assembly at respective capacities of the electrochemical cell assembly corresponding to the open circuit voltage values of the electrochemical cell assembly included in the extracted voltage profile and (ii) the plurality of open circuit voltage values of the electrochemical cell assembly included in the extracted voltage profile.
(A13) In any one of the methods denoted as (A1) through (A12), at least one of the one or more cost functions may include mean of squared differences between (i) capacity of the electrochemical cell assembly, as expressed by the model of the electrochemical cell assembly, at each of the plurality of open circuit voltage values of the electrochemical cell assembly included in the extracted voltage profile, and (ii) capacity of the electrochemical cell assembly, as expressed by the extracted voltage profile, at each of the plurality of open circuit voltage values of the electrochemical cell assembly included in the extracted voltage profile.
(A14) In any one of the methods denoted as (A1) through (A13), at least one of the one or more cost functions may include mean of squared differences between (i) slope of an open circuit voltage versus capacity curve, as expressed by the model of the electrochemical cell assembly, at each of the plurality of open circuit voltage values of the electrochemical cell assembly included in the extracted voltage profile, and (ii) slope of the extracted voltage profile at each of the plurality of open circuit voltage values of the electrochemical cell assembly included in the extracted voltage profile.
(A15) In any one of the methods denoted as (A1) through (A14), the one or more cost functions may include MSE(dVdQ(OCV))+MSE(OCV), where (1) MSE(dVdQ(OCV)) represents mean of squared differences between (i) slope of an open circuit voltage versus capacity curve, as expressed by the model of the electrochemical cell assembly, at each of the plurality of open circuit voltage values of the electrochemical cell assembly included in the extracted voltage profile, and (ii) slope of the extracted voltage profile at each of the plurality of open circuit voltage values of the electrochemical cell assembly included in the extracted voltage profile, and (2) MSE(OCV) represents mean of squared differences between (i) the open circuit voltage values expressed by the model of the electrochemical cell assembly at respective capacities of the electrochemical cell assembly corresponding to the open circuit voltage values of the electrochemical cell assembly included in the extracted voltage profile and (ii) the plurality of the open circuit voltage values of the electrochemical cell assembly included in the extracted voltage profile.
(A16) In any one of the methods denoted as (A1) through (A11), each cost function of the one or more cost functions may be a respective function of one or more of (1) differences between (i) open circuit voltage values expressed by the model of the electrochemical cell assembly at respective capacities of the electrochemical cell assembly corresponding to the open circuit voltage values of the electrochemical cell assembly included in the extracted voltage profile and (ii) the plurality of open circuit voltage values of the electrochemical cell assembly included in the extracted voltage profile, (2) differences between (i) capacity of the electrochemical cell assembly, as expressed by the model of the electrochemical cell assembly, at each of the plurality of open circuit voltage values of the electrochemical cell assembly included in the extracted voltage profile, and (ii) capacity of the electrochemical cell assembly, as expressed by the extracted voltage profile, at each of the plurality of open circuit voltage values of the electrochemical cell assembly included in the extracted voltage profile, and (3) differences between (i) slope of an open circuit voltage versus capacity curve, as expressed by the model of the electrochemical cell assembly, at each of the plurality of open circuit voltage values of the electrochemical cell assembly included in the extracted voltage profile, and (ii) slope of the extracted voltage profile at each of the plurality of open circuit voltage values of the electrochemical cell assembly included in the extracted voltage profile.
(A17) In any one of the methods denoted as (A1) through (A11), each cost function of the one or more cost functions may be a respective weighted function of one or more of (1) differences between (i) open circuit voltage values expressed by the model of the electrochemical cell assembly at respective capacities of the electrochemical cell assembly corresponding to the open circuit voltage values of the electrochemical cell assembly included in the extracted voltage profile and (ii) the plurality of open circuit voltage values of the electrochemical cell assembly included in the extracted voltage profile, (2) differences between (i) capacity of the electrochemical cell assembly, as expressed by the model of the electrochemical cell assembly, at each of the plurality of open circuit voltage values of the electrochemical cell assembly included in the extracted voltage profile, and (ii) capacity of the electrochemical cell assembly, as expressed by the extracted voltage profile, at each of the plurality of open circuit voltage values of the electrochemical cell assembly included in the extracted voltage profile, and (3) differences between (i) slope of an open circuit voltage versus capacity curve, as expressed by the model of the electrochemical cell assembly, at each of the plurality of open circuit voltage values of the electrochemical cell assembly included in the extracted voltage profile, and (ii) slope of the extracted voltage profile at each of the plurality of open circuit voltage values of the electrochemical cell assembly included in the extracted voltage profile.
(A18) In any one of the methods denoted as (A1) through (A17), (1) the one or more cost functions may include at least a first cost function and a second cost function and (2) the step of varying the parameters of the model of the electrochemical cell assembly until the one or more cost functions meet respective predetermined conditions may include (a) varying one or more first parameters of the model of the electrochemical cell assembly until the first cost function meets a first predetermined condition, and (b) after step (a), varying one or more second parameters of the model of the electrochemical cell assembly until the second cost function meets a second predetermined condition, where values of all parameters of the model of the electrochemical cell assembly at the beginning of step (b) are the same as the values of all of the parameters of the model of the electrochemical cell assembly at the end of step (a).
(A19) In the method denoted as (A18), each first parameter of the one or more first parameters of the model of the electrochemical cell assembly may be different from each second parameter of the one or more second parameters of the model of the electrochemical cell assembly.
(A20) In the method denoted as (A18), at least one first parameter of the one or more first parameters of the model of the electrochemical cell assembly may be the same as at least one second parameter of the one or more second parameters of the model of the electrochemical cell assembly.
(A21) Any one of the methods denoted as (A1) through (A20) may further include controlling operation of the electrochemical cell assembly over the one or more operating intervals of the electrochemical cell assembly such that the electrochemical cell assembly is at rest at a plurality of different times over the one or more operating intervals of the electrochemical cell assembly.
(A22) In the method denoted as (A21), controlling operation of the electrochemical cell assembly over the one or more operating intervals of the electrochemical cell assembly may include controlling one or more power converters electrically coupled to the electrochemical cell assembly.
(A23) In the method denoted as (A22), the one or more power converters electrically coupled to the electrochemical cell assembly may include one or more of (i) an inverter and (ii) a direct-current-to-direct-current (DC-to-DC) converter.
(B1) A method for in-situ determination of a thermodynamic state of degradation of an electrochemical cell assembly includes (1) determining charge flowing between the electrochemical cell assembly and external circuitry over the one or more operating intervals of the electrochemical cell assembly, (2) constructing a raw voltage profile from each of (i) the voltage of the electrochemical cell assembly sensed in-situ over the one or more operating intervals of the electrochemical cell assembly and (ii) the charge flowing between the electrochemical cell assembly and the external circuitry over the one or more operating intervals of the electrochemical cell assembly, the raw voltage profile representing voltage of the electrochemical cell assembly as a function of capacity of the electrochemical cell assembly, (3) extracting a subset of the raw voltage profile to obtain an extracted voltage profile, the extracted voltage profile including a plurality of open circuit voltage values of the electrochemical cell assembly, (4) generating one or more differential profiles of the electrochemical cell assembly, the one or more differential profiles including at least one of (i) a generated differential charge profile representing change in capacity of electrochemical cell assembly with respect to change in voltage of the electrochemical cell assembly, as a function of capacity of the electrochemical cell assembly, and (ii) a generated differential voltage profile representing change in voltage of the electrochemical cell assembly with respect to change in capacity of the electrochemical cell assembly, as a function of capacity of the electrochemical cell assembly, (5) varying parameters of a model of the electrochemical cell assembly until a plurality of cost functions meet respective predetermined conditions, each cost function representing error in the model of the electrochemical cell assembly with respect to one or more of (i) data associated with the extracted voltage profile and (ii) data associated with the one or more differential profiles, and (6) after the plurality of cost functions meet their respective predetermined conditions, determining the thermodynamic state of degradation of the electrochemical cell assembly at least partially based on the parameters of the model of the electrochemical cell assembly.
(B2) In the method denoted as (B1), the one or more operating intervals of the electrochemical cell assembly may include a plurality of rest operating states of the electrochemical cell assembly.
(B3) In the method denoted as (B1), (1) the electrochemical cell assembly may be installed in an electric vehicle, and (2) the one or more operating intervals of the electrochemical cell assembly may include (i) one or more time periods where the electrochemical cell assembly either is powering the electric vehicle or is being charged and (ii) a plurality of time periods where the electrochemical cell assembly is at rest.
(B4) In the method denoted as (B1), (1) the electrochemical cell assembly may be installed in a battery energy storage system connected to an electric power grid, and (2) the one or more operating intervals of the electrochemical cell assembly may include (i) one or more time periods where the electrochemical cell assembly either is powering a load or is being charged and (ii) a plurality of time periods where the electrochemical cell assembly is at rest.
(B5) In the method denoted as (B1), (1) the electrochemical cell assembly may be installed in a consumer electronic device, and (2) the one or more operating intervals of the electrochemical cell assembly may include (ii) one or more time periods where the electrochemical cell assembly either is powering the consumer electronic device or is being charged and (ii) one or more time periods where the electrochemical cell assembly is at rest.
(B6) In the method denoted as (B1), (1) the one or more operating intervals of the electrochemical cell assembly may include a plurality of time periods where the electrochemical cell assembly is at rest, and (2) at least three time periods of the plurality of time periods where the electrochemical cell assembly is at rest may correspond to different respective capacities of the electrochemical cell assembly.
(B7) In the method denoted as (B1), (1) the plurality of open circuit voltage values of the electrochemical cell assembly included in the extracted voltage profile may correspond to different respective time periods where the electrochemical cell assembly is at rest, and (2) the method may further include tracking, for each of the time periods where the electrochemical cell assembly is at rest, whether the electrochemical cell assembly was operating in a charging operating mode or in a discharging operating mode immediately before the time period where the electrochemical cell assembly is at rest.
(B8) In any one of the methods denoted as (B1) through (B7), the subset of the raw voltage profile may exclude a portion of the raw voltage profile corresponding to over-potential of the electrochemical cell assembly not having reached a steady-state value.
(B9) In any one of the methods denoted as (B1) through (B8), the subset of the raw voltage profile may exclude a portion of the raw voltage profile where magnitude of over-potential of the electrochemical cell assembly is less than a predetermined threshold value.
(B10) In any one of the methods denoted as (B1) through (B9), the raw voltage profile may represent voltage of the electrochemical cell assembly as a function of capacity of the electrochemical cell assembly during each of (i) charging of the electrochemical cell assembly and (ii) discharging of the electrochemical cell assembly.
(B11) In the method denoted as (B10), the extracted voltage profile may include an average of (i) voltage of the electrochemical cell assembly during charging of the electrochemical cell assembly and (ii) voltage of the electrochemical cell assembly during discharging of the electrochemical cell assembly, as a function of capacity of the electrochemical cell assembly.
(B12) Any one of the methods denoted as (B1) through (B11) may further include selecting the plurality of open circuit voltage values of the electrochemical cell assembly included in the extracted voltage profile such that each open circuit voltage value corresponds to the electrochemical cell assembly operating at rest for at least a predetermined minimum threshold time duration.
(B13) Any one of the methods denoted as (B1) through (B11) may further include selecting the plurality of open circuit voltage values of the electrochemical cell assembly included in the extracted voltage profile such that each open circuit voltage value corresponds to electrochemical cell assembly operating at rest for a predetermined time duration.
(B14) Any one of the methods denoted as (B1) through (B13) may further include selecting the plurality of open circuit voltage values of the electrochemical cell assembly included in the extracted voltage profile such that each of the open circuit voltage values has a common over-potential polarity.
(B15) In any one of the methods denoted as (B1) though (B14), the parameters of the model of the electrochemical cell assembly may include (i) loss of negative electrode material, (ii) loss of positive electrode material, (iii) loss of lithium inventory, and (iv) model capacity offset.
(B16) In any one of the methods denoted as (B1) though (B15), at least one of the plurality of cost functions may include mean of squared differences between (i) open circuit voltage values expressed by the model of the electrochemical cell assembly at respective capacities of the electrochemical cell assembly corresponding to the plurality of open circuit voltage values of the electrochemical cell assembly included in the extracted voltage profile and (ii) the plurality of open circuit voltage values of the electrochemical cell assembly included in the extracted voltage profile.
(B17) In any one of the methods denoted as (B1) though (B16), the one or more differential profiles may include the generated differential charge profile, the plurality of cost functions may include a first cost function and a second cost function, the first cost function may include MSE(OCV), and the second cost function may include MSE(dQdV)+MSE(OCV), where (1) MSE(OCV) represents mean of squared differences between (i) open circuit voltage values expressed by the model of the electrochemical cell assembly corresponding to the plurality of open circuit voltage values of the electrochemical cell assembly included in the extracted voltage profile and (ii) the plurality of open circuit voltage values of the electrochemical cell assembly included in the extracted voltage profile, and (2) MSE(dQdV) represents mean of squared differences between (i) a differential charge profile expressed by the model of the electrochemical cell assembly and (ii) the differential charge profile of the electrochemical cell assembly generated from the extracted voltage profile.
(B18) In any one of the methods denoted as (B1) though (B15), the one or more differential profiles may include the generated differential charge profile, and each cost function of the plurality of cost functions may be a respective function of one or more of (1) differences between (i) open circuit voltage values expressed by the model of the electrochemical cell assembly at respective capacities of the electrochemical cell assembly corresponding to the open circuit voltage values of the electrochemical cell assembly included in the extracted voltage profile and (ii) the plurality of open circuit voltage values of the electrochemical cell assembly included in the extracted voltage profile, (2) differences between (i) capacity of the electrochemical cell assembly, as expressed by the model of the electrochemical cell assembly, at each of the plurality of open circuit voltage values of the electrochemical cell assembly included in the extracted voltage profile, and (ii) capacity of the electrochemical cell assembly, as expressed by the extracted voltage profile, at each of the plurality of open circuit voltage values of the electrochemical cell assembly included in the extracted voltage profile, (3) differences between (i) slope of an open circuit voltage versus capacity curve, as expressed by the model of the electrochemical cell assembly, at each of the plurality of open circuit voltage values of the electrochemical cell assembly included in the extracted voltage profile, and (ii) slope of the extracted voltage profile at each of the plurality of open circuit voltage values of the electrochemical cell assembly included in the extracted voltage profile, and (4) differences between (i) a differential charge profile expressed by the model of the electrochemical cell assembly and (ii) the differential charge profile of the electrochemical cell assembly generated from the extracted voltage profile.
(B19) In any one of the methods denoted as (B1) though (B15), the one or more differential profiles may include the generated differential charge profile, and each cost function of the plurality of cost functions may be a respective weighted function of one or more of (1) differences between (i) open circuit voltage values expressed by the model of the electrochemical cell assembly at respective capacities of the electrochemical cell assembly corresponding to the open circuit voltage values of the electrochemical cell assembly included in the extracted voltage profile and (ii) the plurality of open circuit voltage values of the electrochemical cell assembly included in the extracted voltage profile, (2) differences between (i) capacity of the electrochemical cell assembly, as expressed by the model of the electrochemical cell assembly, at each of the plurality of open circuit voltage values of the electrochemical cell assembly included in the extracted voltage profile, and (ii) capacity of the electrochemical cell assembly, as expressed by the extracted voltage profile, at each of the plurality of open circuit voltage values of the electrochemical cell assembly included in the extracted voltage profile, (3) differences between (i) slope of an open circuit voltage versus capacity curve, as expressed by the model of the electrochemical cell assembly, at each of the plurality of open circuit voltage values of the electrochemical cell assembly included in the extracted voltage profile, and (ii) slope of the extracted voltage profile at each of the plurality of open circuit voltage values of the electrochemical cell assembly included in the extracted voltage profile, and (4) differences between (i) a differential charge profile expressed by the model of the electrochemical cell assembly and (ii) the differential charge profile of the electrochemical cell assembly generated from the extracted voltage profile.
(B20) In any one of the methods denoted as (B1) though (B19), the one or more cost functions may include at least a first cost function and a second cost function, and the step of varying the parameters of the model of the electrochemical cell assembly until the one or more cost functions meet respective predetermined conditions may include (a) varying one or more first parameters of the model of the electrochemical cell assembly until the first cost function meets a first predetermined condition, and (b) after step (a), varying one or more second parameters of the model of the electrochemical cell assembly until the second cost function meets a second predetermined condition, where values of all parameters of the model of the electrochemical cell assembly at the beginning of step (b) are the same as the values of all of the parameters of the model of the electrochemical cell assembly at the end of step (a).
(B21) In the method denoted as (B20), each first parameter of the one or more first parameters of the model of the electrochemical cell assembly may be different from each second parameter of the one or more second parameters of the model of the electrochemical cell assembly.
(B22) In the method denoted as (B20), at least one first parameter of the one or more first parameters of the model of the electrochemical cell assembly may be the same as at least one second parameter of the one or more second parameters of the model of the electrochemical cell assembly.
(B23) Any one of the methods denoted as (B1) through (B22) may further include controlling operation of the electrochemical cell assembly over the one or more operating intervals of the electrochemical cell assembly such that the electrochemical cell assembly is at rest at a plurality of different times over the one or more operating intervals of the electrochemical cell assembly.
(B24) In the method denoted as (B23), controlling operation of the electrochemical cell assembly over the one or more operating intervals of the electrochemical cell assembly may include controlling one or more power converters electrically coupled to the electrochemical cell assembly.
(B25) In the method denoted as (B24), the one or more power converters electrically coupled to the electrochemical cell assembly may include one or more of (i) an inverter and (ii) a direct-current-to-direct-current (DC-to-DC) converter.

Changes may be made in the above methods, devices, and systems without departing from the scope hereof. It should thus be noted that the matter contained in the above description and shown in the accompanying drawings should be interpreted as illustrative and not in a limiting sense. The following claims are intended to cover generic and specific features described herein, as well as all statements of the scope of the present method and system, which as a matter of language, might be said to fall therebetween.

What is claimed is:

1. A method for in-situ determination of a thermodynamic state of degradation of an electrochemical cell assembly, the method comprising:
sensing voltage of the electrochemical cell assembly in-situ over one or more operating intervals of the electrochemical cell assembly to generate sensed voltage data;
determining charge flowing between the electrochemical cell assembly and external circuitry over the one or more operating intervals of the electrochemical cell assembly to generate sensed charge data;
constructing a raw voltage profile from each of (i) the sensed voltage data and (ii) the sensed charge data, the raw voltage profile representing voltage of the electrochemical cell assembly as a function of capacity of the electrochemical cell assembly;
extracting a subset of the raw voltage profile to obtain an extracted voltage profile, the extracted voltage profile including a plurality of open circuit voltage values of the electrochemical cell assembly;
varying parameters of a model of the electrochemical cell assembly until one or more cost functions meet respective predetermined conditions, each cost function representing error in the model of the electrochemical cell assembly with respect to data associated with the extracted voltage profile; and
after the one or more cost functions meet their respective predetermined conditions, determining the thermodynamic state of degradation of the electrochemical cell assembly at least partially based on the parameters of the model of the electrochemical cell assembly.

2. The method of claim 1, wherein the one or more operating intervals of the electrochemical cell assembly include a plurality of rest operating states of the electrochemical cell assembly which are at various states of charge.

3. The method of claim 1, wherein:
the plurality of open circuit voltage values of the electrochemical cell assembly included in the extracted voltage profile correspond to different respective time periods where the electrochemical cell assembly is at rest; and
the method further comprises:
tracking, for each of the time periods where the electrochemical cell assembly is at rest, whether the electrochemical cell assembly was operating in a charging operating mode or in a discharging operating mode immediately before the time period where the electrochemical cell assembly is at rest, and
selecting the plurality of open circuit voltage values of the electrochemical cell assembly included in the extracted voltage profile such that each of the open circuit voltage values has a common over-potential polarity.

4. The method of claim 1, further comprising selecting the plurality of open circuit voltage values of the electrochemical cell assembly included in the extracted voltage profile such that either (i) each open circuit voltage value corresponds to the electrochemical cell assembly operating at rest for at least a predetermined minimum threshold time duration or (ii) each open circuit voltage value corresponds to the electrochemical cell assembly operating at rest for a predetermined time duration.

5. The method of claim 1, wherein the parameters of the model of the electrochemical cell assembly comprise (i) loss of negative electrode material, (ii) loss of positive electrode material, (iii) loss of lithium inventory, and (iv) model capacity offset.

6. The method of claim 1, wherein each cost function of the one or more cost functions is a respective function of one or more of:
(1) differences between (i) open circuit voltage values expressed by the model of the electrochemical cell assembly at respective capacities of the electrochemical cell assembly corresponding to the open circuit voltage values of the electrochemical cell assembly included in the extracted voltage profile and (ii) the plurality of open circuit voltage values of the electrochemical cell assembly included in the extracted voltage profile;
(2) differences between (i) capacity of the electrochemical cell assembly, as expressed by the model of the electrochemical cell assembly, at each of the plurality of open circuit voltage values of the electrochemical cell assembly included in the extracted voltage profile, and (ii) capacity of the electrochemical cell assembly, as expressed by the extracted voltage profile, at each of the plurality of open circuit voltage values of the electrochemical cell assembly included in the extracted voltage profile; and
(3) differences between (i) slope of an open circuit voltage versus capacity curve, as expressed by the model of the electrochemical cell assembly, at each of the plurality of open circuit voltage values of the electrochemical cell assembly included in the extracted voltage profile, and (ii) slope of the extracted voltage profile at each of the plurality of open circuit voltage values of the electrochemical cell assembly included in the extracted voltage profile.

7. The method of claim 1, wherein each cost function of the one or more cost functions is a respective weighted function of one or more of:
(1) differences between (i) open circuit voltage values expressed by the model of the electrochemical cell assembly at respective capacities of the electrochemical cell assembly corresponding to the open circuit voltage values of the electrochemical cell assembly included in the extracted voltage profile and (ii) the plurality of open circuit voltage values of the electrochemical cell assembly included in the extracted voltage profile;
(2) differences between (i) capacity of the electrochemical cell assembly, as expressed by the model of the electrochemical cell assembly, at each of the plurality of open circuit voltage values of the electrochemical cell assembly included in the extracted voltage profile, and (ii) capacity of the electrochemical cell assembly, as expressed by the extracted voltage profile, at each of the plurality of open circuit voltage values of the electrochemical cell assembly included in the extracted voltage profile; and
(3) differences between (i) slope of an open circuit voltage versus capacity curve, as expressed by the model of the electrochemical cell assembly, at each of the plurality of open circuit voltage values of the electrochemical cell assembly included in the extracted voltage profile, and (ii) slope of the extracted voltage profile at each of the plurality of open circuit voltage values of the electrochemical cell assembly included in the extracted voltage profile.

8. The method of claim 1, wherein:
the one or more cost functions comprise at least a first cost function and a second cost function; and
the step of varying the parameters of the model of the electrochemical cell assembly until the one or more cost functions meet respective predetermined conditions comprises:
(a) varying one or more first parameters of the model of the electrochemical cell assembly until the first cost function meets a first predetermined condition, and
(b) after step (a), varying one or more second parameters of the model of the electrochemical cell assembly until the second cost function meets a second predetermined condition,
wherein values of all parameters of the model of the electrochemical cell assembly at the beginning of step (b) are the same as the values of all of the parameters of the model of the electrochemical cell assembly at the end of step (a).

9. The method of claim 8, wherein either (i) each first parameter of the one or more first parameters of the model of the electrochemical cell assembly is different from each second parameter of the one or more second parameters of the model of the electrochemical cell assembly or (ii) at least one first parameter of the one or more first parameters of the model of the electrochemical cell assembly is the same as at least one second parameter of the one or more second parameters of the model of the electrochemical cell assembly.

10. The method of claim 1, further comprising controlling operation of the electrochemical cell assembly over the one or more operating intervals of the electrochemical cell assembly such that the electrochemical cell assembly is at rest at a plurality of different times over the one or more operating intervals of the electrochemical cell assembly.

11. The method of claim 10, wherein controlling operation of the electrochemical cell assembly over the one or more operating intervals of the electrochemical cell assembly comprises controlling one or more power converters electrically coupled to the electrochemical cell assembly.

12. A method for in-situ determination of a thermodynamic state of degradation of an electrochemical cell assembly, the method comprising:
sensing voltage of the electrochemical cell assembly in-situ over one or more operating intervals of the electrochemical cell assembly;
determining charge flowing between the electrochemical cell assembly and external circuitry over the one or more operating intervals of the electrochemical cell assembly;
constructing a raw voltage profile from each of (i) the voltage of the electrochemical cell assembly sensed in-situ over the one or more operating intervals of the electrochemical cell assembly and (ii) the charge flowing between the electrochemical cell assembly and the external circuitry over the one or more operating intervals of the electrochemical cell assembly, the raw voltage profile representing voltage of the electrochemical cell assembly as a function of capacity of the electrochemical cell assembly;
extracting a subset of the raw voltage profile to obtain an extracted voltage profile, the extracted voltage profile including a plurality of open circuit voltage values of the electrochemical cell assembly;
generating one or more differential profiles of the electrochemical cell assembly, the one or more differential profiles including at least one of (i) a generated differential charge profile representing change in capacity of electrochemical cell assembly with respect to change in voltage of the electrochemical cell assembly, as a function of capacity of the electrochemical cell assembly, and (ii) a generated differential voltage profile representing change in voltage of the electrochemical cell assembly with respect to change in capacity of the electrochemical cell assembly, as a function of capacity of the electrochemical cell assembly;
varying parameters of a model of the electrochemical cell assembly until a plurality of cost functions meet respective predetermined conditions, each cost function representing error in the model of the electrochemical cell assembly with respect to one or more of (i) data associated with the extracted voltage profile and (ii) data associated with the one or more differential profiles; and
after the plurality of cost functions meet their respective predetermined conditions, determining the thermodynamic state of degradation of the electrochemical cell assembly at least partially based on the parameters of the model of the electrochemical cell assembly.

13. The method of claim 12, wherein the one or more operating intervals of the electrochemical cell assembly include a plurality of rest operating states of the electrochemical cell assembly.

14. The method of claim 12, wherein the subset of the raw voltage profile excludes at least one of (i) a portion of the raw voltage profile corresponding to over-potential of the electrochemical cell assembly not having reached a steady-state value and (ii) a portion of the raw voltage profile where magnitude of over-potential of the electrochemical cell assembly is less than a predetermined threshold value.

15. The method of claim 12, wherein the raw voltage profile represents voltage of the electrochemical cell assembly as a function of capacity of the electrochemical cell assembly during each of (i) charging of the electrochemical cell assembly and (ii) discharging of the electrochemical cell assembly.

16. The method of claim 15, wherein the extracted voltage profile includes an average of (i) voltage of the electrochemical cell assembly during charging of the electrochemical cell assembly and (ii) voltage of the electrochemical cell assembly during discharging of the electrochemical cell assembly, as a function of capacity of the electrochemical cell assembly.

17. The method of claim 12, wherein the parameters of the model of the electrochemical cell assembly comprise (i) loss of negative electrode material, (ii) loss of positive electrode material, (iii) loss of lithium inventory, and (iv) model capacity offset.

18. The method of claim 12, wherein the one or more differential profiles include the generated differential charge profile, and each cost function of the plurality of cost functions is a respective function of one or more of:
(1) differences between (i) open circuit voltage values expressed by the model of the electrochemical cell assembly at respective capacities of the electrochemical cell assembly corresponding to the open circuit voltage values of the electrochemical cell assembly included in the extracted voltage profile and (ii) the plurality of open circuit voltage values of the electrochemical cell assembly included in the extracted voltage profile;
(2) differences between (i) capacity of the electrochemical cell assembly, as expressed by the model of the electrochemical cell assembly, at each of the plurality of open circuit voltage values of the electrochemical cell assembly included in the extracted voltage profile, and (ii) capacity of the electrochemical cell assembly, as expressed by the extracted voltage profile, at each of the plurality of open circuit voltage values of the electrochemical cell assembly included in the extracted voltage profile;
(3) differences between (i) slope of an open circuit voltage versus capacity curve, as expressed by the model of the electrochemical cell assembly, at each of the plurality of open circuit voltage values of the electrochemical cell assembly included in the extracted voltage profile, and (ii) slope of the extracted voltage profile at each of the plurality of open circuit voltage values of the electrochemical cell assembly included in the extracted voltage profile; and
(4) differences between (i) a differential charge profile expressed by the model of the electrochemical cell assembly and (ii) the generated differential charge profile.

19. The method of claim 12, wherein the one or more differential profiles include the generated differential charge profile, and each cost function of the plurality of cost functions is a respective weighted function of one or more of:
(1) differences between (i) open circuit voltage values expressed by the model of the electrochemical cell assembly at respective capacities of the electrochemical cell assembly corresponding to the open circuit voltage values of the electrochemical cell assembly included in the extracted voltage profile and (ii) the plurality of open circuit voltage values of the electrochemical cell assembly included in the extracted voltage profile;
(2) differences between (i) capacity of the electrochemical cell assembly, as expressed by the model of the electrochemical cell assembly, at each of the plurality of open circuit voltage values of the electrochemical cell assembly included in the extracted voltage profile, and (ii) capacity of the electrochemical cell assembly, as expressed by the extracted voltage profile, at each of the plurality of open circuit voltage values of the electrochemical cell assembly included in the extracted voltage profile;
(3) differences between (i) slope of an open circuit voltage versus capacity curve, as expressed by the model of the electrochemical cell assembly, at each of the plurality of open circuit voltage values of the electrochemical cell assembly included in the extracted voltage profile, and (ii) slope of the extracted voltage profile at each of the plurality of open circuit voltage values of the electrochemical cell assembly included in the extracted voltage profile; and
(4) differences between (i) a differential charge profile expressed by the model of the electrochemical cell assembly and (ii) the generated differential charge profile of the electrochemical cell assembly.

20. The method of claim 12, wherein:
the one or more cost functions comprise at least a first cost function and a second cost function; and
the step of varying the parameters of the model of the electrochemical cell assembly until the one or more cost functions meet respective predetermined conditions comprises:
(a) varying one or more first parameters of the model of the electrochemical cell assembly until the first cost function meets a first predetermined condition, and
(b) after step (a), varying one or more second parameters of the model of the electrochemical cell assembly until the second cost function meets a second predetermined condition,
wherein values of all parameters of the model of the electrochemical cell assembly at the beginning of step (b) are the same as the values of all of the parameters of the model of the electrochemical cell assembly at the end of step (a).

21. The method of claim 12, further comprising controlling operation of the electrochemical cell assembly over the one or more operating intervals of the electrochemical cell assembly such that the electrochemical cell assembly is at rest at a plurality of different times over the one or more operating intervals of the electrochemical cell assembly.

22. The method of claim 12, wherein controlling operation of the electrochemical cell assembly over the one or more operating intervals of the electrochemical cell assembly comprises controlling one or more power converters electrically coupled to the electrochemical cell assembly.
